(19) United States
(12) Patent Application Publication
(10) Pub. No.: US 2008/0143423 A1
(43) Pub. Date: Jun. 19, 2008

(54) SEMICONDUCTOR INTEGRATED CIRCUIT AND MANUFACTURING METHOD THEREFOR

(76) Inventors: Shigenobu Komatsu, Kokubunji (JP); Kenichi Osada, Tokyo (JP); Masanao Yamaoka, Kodaira (JP); Koichiro Ishibashi, Warabi (JP)

Correspondence Address: MILES & STOCKBRIDGE PC, 1751 PINNACLE DRIVE, SUITE 500, MCLEAN, VA, 22102-3833, US

(21) Appl. No.: 11/943,095

(22) Filed: Nov. 20, 2007

(30) Foreign Application Priority Data
Dec. 18, 2006 (JP) 2006-339437

(51) Int. Cl. H03K 3/01; H01L 21/8238

(52) U.S. Cl. 327/534; 438/199; 257/E21.632

(57) ABSTRACT

The present invention is directed to realize high manufacture yield and compensate variations in threshold voltage of a MOS transistor with small overhead. A semiconductor integrated circuit includes a CMOS circuit for processing an input signal in an active mode, a control switch, and a control memory. The control switch supplies a pMOS body bias voltage and an nMOS body bias voltage to an N well in a pMOS transistor and a P well in an nMOS transistor, respectively, in the CMOS circuit. The control memory stores control information indicating whether or not the pMOS body bias voltage and the nMOS body bias voltage are supplied from the control switch to the N well in the pMOS transistor and the P well in the nMOS transistor, respectively, in the CMOS circuit in the active mode.

### CLAIM OF PRIORITY

The present application claims priority from Japanese application JP2006-339437 filed on Dec. 18, 2006, the content of which is hereby incorporated by reference into this application.

### FIELD OF THE INVENTION

The present invention relates to a semiconductor integrated circuit and a method of manufacturing the same. More particularly, the invention relates to the technique useful for realizing higher manufacture yield and compensating variations in threshold voltage of a MOS transistor with small overhead.

### BACKGROUND OF THE INVENTION

Due to the short channel effect produced as a semiconductor device is becoming finer, the threshold voltage of a MOS transistor is decreasing and increase in the subthreshold leakage current is becoming apparent. The characteristic equal to or less than the threshold voltage of the MOS transistor is the subthreshold characteristic, and leakage current in a state where the surface of MOS silicon is weakly inverted is called subthreshold leakage current. As a method of reducing such leakage current, the body bias technique is well known. By applying a predetermined body bias voltage to a semiconductor substrate (called a well in the case of a CMOS) in which a MOS transistor is formed, the subthreshold leakage current can be reduced.

The following non-patent document 1 describes a method of switching body bias voltage between an active mode and a standby mode. In the active mode, an nMOS body bias voltage Vbn applied to a P-well in an nMOS of a CMOS is set to a ground voltage Vss (0 volt) which is applied to an N-type source of the nMOS. A pMOS body bias voltage Vbp applied to an N-well in a pMOS of the CMOS is set to a power source voltage Vdd (1.8 volts). In the standby mode in which the subthreshold leakage current is reduced, the nMOS body bias voltage Vbn applied to the P-well is set to a negative voltage (−1.5 volts) of reverse body bias with respect to the ground voltage Vss (0 volt) applied to the N-type source of the nMOS of the CMOS. The PMOS body bias voltage Vbp applied to the N-well is set to a positive voltage (3.3 volts) of the reverse body bias with respect to the power source voltage Vdd (1.8 volts) applied to the P-type source of the pMOS of the CMOS.

The following non-patent document 2 describes control on supply of the pMOS body bias voltage Vbp, the nMOS body bias voltage Vbn, the power source voltage Vdd, and a clock signal to the MOS module in order to make a chip operate with the maximum performance per power consumption. For the control, an adaptive-universal controller including a compound BIST (Built-In Self Test) circuit for measuring the characteristic of a CMOS module and a self-instruction lookup table is used. As a result, when the amount of data to be processed is small, the average power consumption of the chip is lower.

### Non-Patent Document 1

Hiroyuki Mizuno et al, “A 18 μA-Standby-Current 1.8V 200 MHz Microprocessor with Self Substrate-Biased Data-Retention Mode”, 1999 IEEE International Solid-State Circuits Conference DIGEST OF TECHNICAL PAPERS, pp. 280-281, 468.

### Non-Patent Documents 2

Masayuki Miyazaki et al, “An Autonomous Decentralized Low-Power System with Adaptive-Universal Control for a Chip Multi-Processor, 2003 IEEE International Solid-State Circuits Conference DIGEST OF TECHNICAL PAPERS, ISSCC 2003/SESSION 6/LOW-POWER DIGITAL TECHNIQUES/PAPER 6.4

### SUMMARY OF THE INVENTION

The conventional body bias technique described in the non-patent document 1 is directed to reduce the subthreshold leakage current in the standby mode caused by decrease in the threshold voltage of the MOS transistor as the semiconductor device is becoming finer. However, as the semiconductor device is becoming finer and finer, variations in the threshold voltage of the MOS transistor among chips are becoming apparent. Specifically, when the threshold voltage of the MOS transistor is too low, the operation power consumption increases remarkably in the active mode in which the semiconductor integrated circuit performs processes on a digital input signal and an analog digital signal. On the other hand, when the threshold voltage of the MOS transistor is too high, the operation speed drops remarkably in the active mode in which the semiconductor integrated circuit performs processes on a digital input signal and an analog input signal. As a result, the process window of the threshold voltage of the MOS transistor at the time of manufacturing a MOS LSI is extremely narrow, and the manufacture yield of the MOS LSI is remarkably low.

On the other hand, the adaptive control circuit for controlling a body bias voltage, a power source voltage, and a clock frequency described in the non-patent document 2 can make a chip operate with the maximum performance per power consumption and, in addition, compensate variations among chips. However, it was found out that the adaptive control circuit described in the non-patent document 2 has problems such that overhead of the occupation area in the chip is large, the control is complicated, and it is difficult to design the circuit.

Therefore, an object of the present invention is to realize higher manufacture yield and compensate variations in threshold voltage of a MOS transistor with small overhead.

The above and other objects and novel features of the present invention will become apparent from the description of the specification and the appended drawings.

Representative ones of inventions disclosed in the application will be briefly described as follows.

In a representative semiconductor integrated circuit of the present invention, an active body bias technique is employed. In the active body bias technique, a body bias voltage is applied to the substrate of a MOS transistor in an active mode in which the semiconductor integrated circuit processes an input signal. In the active body bias technique, first, a threshold voltage of the MOS transistor is measured. If the threshold voltage varies largely, the level of the body bias voltage is adjusted to control the variations to a predetermined error range. To the substrate (well) of the MOS transistor, a body bias voltage of a reverse body bias or an extremely shallow forward body bias of the operation voltage applied to the source of the MOS transistor is applied. By employing the active body bias technique in such a manner, high manufacture yield can be achieved and variations in the threshold voltage of the MOS transistor can be compensated with small overhead.

An effect obtained by the representative one of the inventions disclosed in the application will be briefly described as follows.

According to the present invention, high manufacture yield can be achieved and variations in the threshold voltage of the MOS transistor can be compensated with small overhead.

### BRIEF DESCRIPTION OF THE DRAWINGS

FIG. 1 is a circuit diagram showing a semiconductor integrated circuit as an embodiment of the present invention capable of compensating variations among LSI chips by a bias control on a well in a substrate of a MOS transistor.

FIGS. 2A and 2B are circuit diagrams showing an example of the configuration of a control memory of the LSI chip illustrated in FIG. 1.

FIG. 3 is a diagram showing the relations among voltages in parts of the semiconductor integrated circuit illustrated in FIG. 1.

FIGS. 4A and 4B are diagrams illustrating distributions of threshold voltages of a manufactured MOS LSI.

FIG. 5 is a diagram showing a layout in which a control memory and a control switch are disposed around a core CMOS logic circuit in the LSI chip.

FIG. 6 is a diagram showing a layout in which a plurality of control switches each corresponding to the control switch in FIG. 1 are disposed in the core CMOS logic circuit in the LSI chip.

FIG. 7 is a diagram showing another layout in which a plurality of control switches each corresponding to the control switch in FIG. 1 are disposed in the core CMOS logic circuit in the LSI chip.

FIG. 8 is a diagram for explaining a test on a wafer including a number of LSI chips illustrated in FIG. 1.

FIG. 9 is a diagram showing a method of manufacturing a semiconductor integrated circuit, including a flow of the wafer test and wafer process.

FIG. 10 is a circuit diagram showing a semiconductor integrated circuit as another embodiment of the present invention.

FIG. 11 is a circuit diagram showing a semiconductor integrated circuit as further another embodiment of the present invention.

FIG. 12 is a circuit diagram showing a semiconductor integrated circuit as further another embodiment of the present invention.

FIG. 13 is a circuit diagram showing a semiconductor integrated circuit as further another embodiment of the present invention.

FIG. 14 is a circuit diagram showing a semiconductor integrated circuit as further another embodiment of the present invention.

FIG. 15 is a diagram showing fluctuations in the electric characteristics of a core CMOS logic circuit due to variations in an nMOS threshold voltage and the absolute value of a pMOS threshold voltage of a core CMOS logic circuit.

FIGS. 16A to 16E are circuit diagrams showing a semiconductor integrated circuit as further another embodiment of the present invention.

FIGS. 17A to 17C are circuit diagrams showing a semiconductor integrated circuit as further another embodiment of the present invention.

FIGS. 18A and 18B are circuit diagrams showing a semiconductor integrated circuit as further another embodiment of the present invention.

FIG. 19 is a circuit diagram showing a semiconductor integrated circuit as further another embodiment of the present invention.

FIG. 20 is a circuit diagram showing a semiconductor integrated circuit as further another embodiment of the present invention.

FIG. 21 is a circuit diagram showing a semiconductor integrated circuit as further another embodiment of the present invention.

FIG. 22 is a circuit diagram showing a semiconductor integrated circuit as further another embodiment of the present invention.

FIG. 23 is a circuit diagram showing a semiconductor integrated circuit as further another embodiment of the present invention.

FIGS. 24A and 24B are diagrams illustrating distributions of threshold voltages of the semiconductor integrated circuit shown in FIG. 23.

FIG. 25 is a diagram showing the relations among voltages in parts of the semiconductor integrated circuit illustrated in FIG. 23.

FIG. 26 is a circuit diagram showing a semiconductor integrated circuit as further another embodiment of the invention.

FIG. 27 is a circuit diagram showing a embedded SRAM formed in a chip of a semiconductor integrated circuit together with the core CMOS logic circuit illustrated in FIGS. 1 to 26.

FIGS. 28A and 28B are diagrams showing electric characteristics of an SRAM memory cell depending on variations in an nMOS threshold voltage and the absolute value of a pMOS threshold voltage in the SRAM memory cell.

FIG. 29 is a diagram showing changes in a pMOS body bias voltage of a load pMOS in an SRAM memory cell and an nMOS body bias voltage of a driver nMOS and a transfer nMOS in the SRAM memory cell caused by level changes in output signals of control memories.

FIG. 30 is a diagram showing body bias voltages applied to chips corresponding to areas close to a limit line of reading operation and a limit line of writing operation depending on level changes in the output signal of the control memories.

FIG. 31 is a diagram showing a system LSI including a CPU core, a logic core, an SRAM core, and an analog core in the chip.

FIG. 32 is a diagram showing a sectional structure of a semiconductor integrated circuit as further another embodiment of the invention.

### DETAILED DESCRIPTION OF THE PREFERRED EMBODIMENTS

### Representative Embodiments

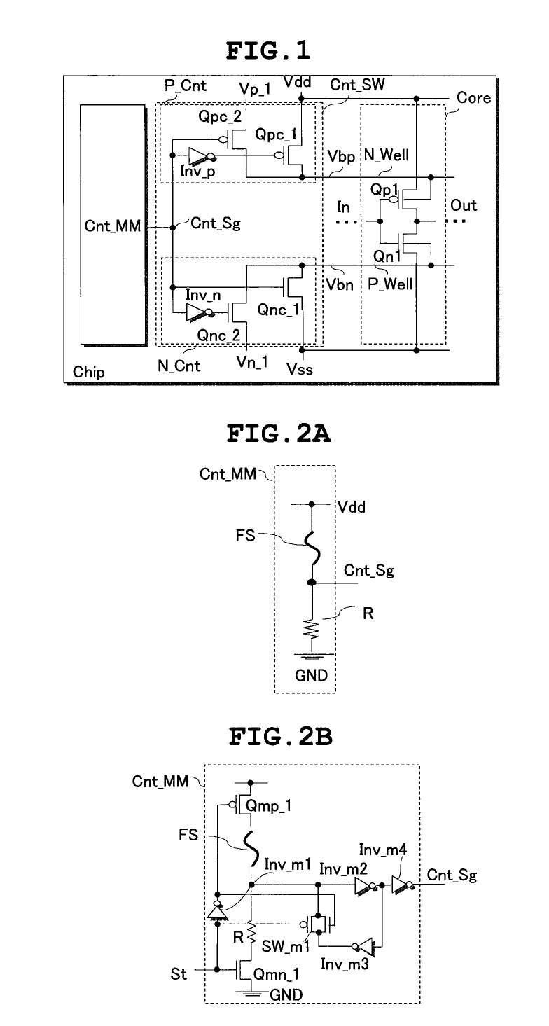

First, outline of representative embodiments of the present invention disclosed in the application will be described. Reference numerals in the drawings described in parenthesis in the representative embodiments just illustrate parts included in the concept of the components.
[1] A semiconductor integrated circuit (Chip) as a representative embodiment of the present invention includes a CMOS circuit (Core) for processing an input signal (In) in an active mode. The semiconductor integrated circuit further includes a control switch (Cnt_SW) for supplying a pMOS body bias voltage (Vbp) and an nMOS body bias voltage (Vbn) to an N well (N_Well) in a pMOS transistor (Qp1) and a P well (P_Well) in an nMOS transistor (Qn1), respectively, in the CMOS circuit. The semiconductor integrated circuit further includes a control memory (Cnt_MM) for storing at least control information (Cnt_Sg) indicating whether or not the pMOS body bias voltage and the nMOS body bias voltage are supplied from the control switch to the N well in the PMOS transistor and the P well in the nMOS transistor, respectively, in the CMOS circuit in the active mode (refer to FIG. 1).

Therefore, in the embodiment, in the case where the threshold voltage of any of the pPMOS and nMOS transistors in the CMOS circuit is too low, the control information stored in the control memory is set to a low threshold state. From the control switch controlled by the control information stored in the control memory, the pMOS body bias voltage and the nMOS body bias voltage as reverse body bias voltages of the source operation voltage are supplied to the N well in the PMOS transistor and the P well in the nMOS transistor in the CMOS circuit. As a result, the pMOS and nMOS threshold voltages in the CMOS circuit increase from values which are too low to proper values, and the operation power consumption in the active mode in which signal process is performed can be reduced.

In the case where the pMOS and nMOS threshold voltages in the CMOS circuit are proper, the control information stored in the control memory is set to a proper threshold state. From the control switch controlled by the control information stored in the control memory, the pMOS body bias voltage and the nMOS body bias voltage having almost the same voltage level as that of the source operation voltage are supplied to the N well in the pMOS transistor and the P well in the nMOS transistor in the CMOS circuit. As a result, the threshold voltages of the pMOS and nMOS transistors in the CMOS circuit are maintained at proper values, and the operation power consumption in the active mode in which the signal process is performed can be also maintained to a proper value.

In the case where the pMOS and nMOS threshold voltages in the CMOS circuit are too high, the control information stored in the control memory is set to a high threshold state. From the control switch controlled by the control information stored in the control memory, the pMOS body bias voltage and the nMOS body bias voltage as forward body bias voltages of the source operation voltage are supplied to the N well in the pMOS transistor and the P well in the nMOS transistor in the CMOS circuit. As a result, the threshold voltages which are too high of the PMOS and nMOS transistors in the CMOS circuit are decreased to proper values, and the operation speed in the active mode in which the signal process is performed can be improved.

With the configuration, in the embodiment, high manufacture yield can be achieved, and variations in the threshold voltage of a MOS transistor can be compensated with small overhead.

In the semiconductor integrated circuit as a preferred embodiment, the control memory is a nonvolatile memory. Information determining whether at least one of threshold voltages of the pMOS transistor and the nMOS transistor in the CMOS circuit is low or not can be stored in the nonvolatile memory as the control memory (refer to FIGS. 2, 3, 4, 8, and 9).

Therefore, in the preferred embodiment, only by performing the determination once to see whether at least one of the threshold voltages of the PMOS and nMOS transistors in the CMOS circuit is low or not, variations in the threshold voltages of the pMOS and nMOS transistors in the CMOS circuit can be compensated.

In the semiconductor integrated circuit according to a more preferable embodiment, a first operation voltage (Vdd) is supplied to a source of the pMOS transistor in the CMOS circuit and a second operation voltage (Vss) is supplied to a source of the nMOS transistor. The semiconductor integrated circuit further includes: a first voltage generator (CP_P) for generating the PMOS body bias voltage higher than the first operation voltage; and a second voltage generator (CP_N) for generating the nMOS body bias voltage lower than the second operation voltage.

Therefore, in the more preferred embodiment, the pMOS body bias voltage and the nMOS body bias voltage can be generated by the reduced number of operation voltage supply terminals.

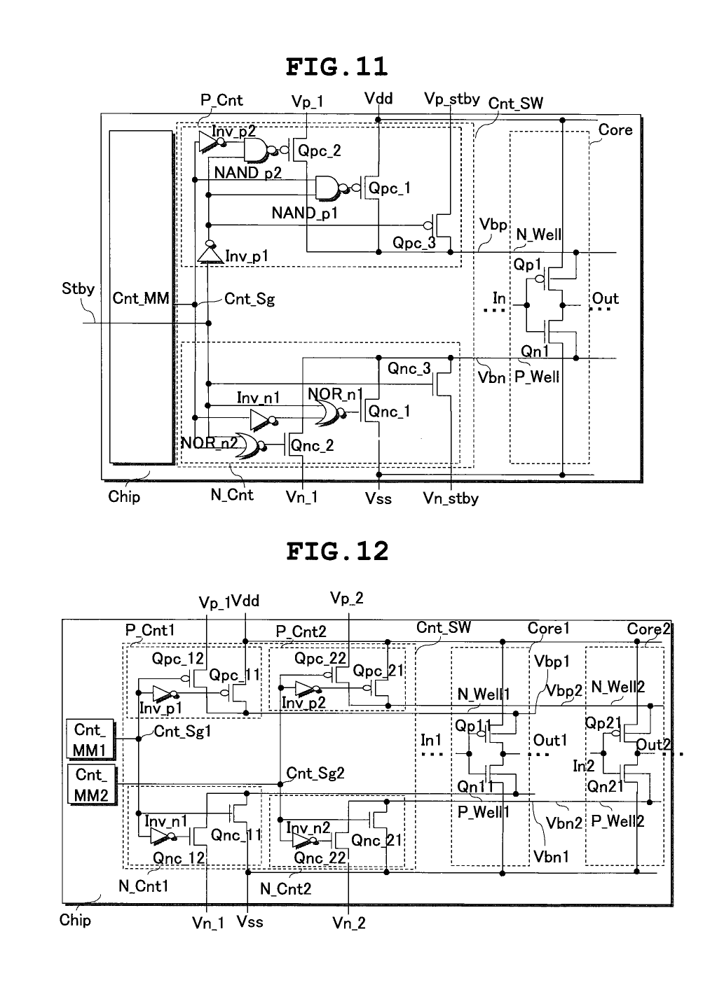

In a semiconductor integrated circuit according to a more preferred embodiment, a first operation voltage (Vdd) is supplied to a source of the pMOS transistor and a second operation voltage (Vss) is supplied to a source of the nMOS transistor in the CMOS circuit. The control switch applies an N-well standby voltage (Vp_stby) higher than the pMOS body bias voltage (Vp_1) as a reverse body bias of the first operation voltage to the N well in the pMOS transistor in a standby mode. The control switch applies a P-well standby voltage (Vn_stby) lower than the nMOS body bias voltage (Vn_1) as a reverse body bias of the second operation voltage to the P well in the nMOS transistor in the standby mode (refer to FIG. 11).

Therefore, in the more preferred embodiment, the standby leakage currents in the pMOS and nMOS transistors in the CMOS circuit can be largely reduced.

In a semiconductor integrated circuit as a concrete embodiment, a first operation voltage is supplied to a source of the pMOS transistor and a second operation voltage is supplied to a source of the nMOS transistor in the CMOS circuit. The pMOS body bias voltage supplied to the N well is set as a reverse body bias of the first operation voltage supplied to the source of the pMOS transistor in the CMOS circuit. The nMOS body bias voltage supplied to the P well is set as a reverse body bias of the second operation voltage supplied to the source of the nMOS transistor in the CMOS circuit. By supplying the pMOS body bias voltage set to a level higher than the first operation voltage to the N well, the pMOS transistor having the N well is controlled in a state of a high threshold voltage and a low leakage current. By supplying the nMOS body bias voltage set at a level lower than the second operation voltage to the P well, the nMOS transistor having the P well is controlled in a state of a high threshold voltage and a low leakage current (refer to FIGS. 4A and 4B).

In a semiconductor integrated circuit as a further another concrete embodiment, a first operation voltage is supplied to a source of the pMOS transistor and a second operation voltage is supplied to a source of the nMOS transistor in the CMOS circuit. The PMOS body bias voltage supplied to the N well is set as a forward body bias of the first operation voltage supplied to the source of the pMOS transistor in the CMOS circuit. The nMOS body bias voltage supplied to the P well is set as a forward body bias of the second operation voltage supplied to the source of the nMOS transistor in the CMOS circuit. By supplying the pMOS body bias voltage set to a level lower than the first operation voltage to the N well, the pMOS transistor having the N well is controlled in a state of a low threshold voltage and a high leakage current. By supplying the nMOS body bias voltage set at a level higher than the second operation voltage to the P well, the nMOS transistor having the P well is controlled in a state of a low threshold voltage and a high leakage current (refer to FIGS. 24A and 24B).

In the semiconductor integrated circuit as further another concrete embodiment, the control switch includes: a first control switch (P_Cnt) for supplying the pMOS body bias voltage to the N well in the pMOS transistor of the CMOS circuit; and a second control switch (N_Cnt) for supplying the nMOS body bias voltage to the P well in the nMOS transistor in the CMOS circuit. The control memory includes a first control memory (Cnt_MM_p) and a second control memory (Cnt_MM_n). The first control memory stores at least first control information (Cnt_Sg_p) indicating whether or not the pMOS body bias voltage is supplied from the first control switch to the N well in the pMOS transistor in the CMOS circuit in the active mode. The second control memory stores at least second control information (Cnt_Sg_n) indicating whether or not the nMOS body bias voltage is supplied from the second control switch to the P well in the nMOS transistor in the CMOS circuit in the active mode (refer to FIG. 14).

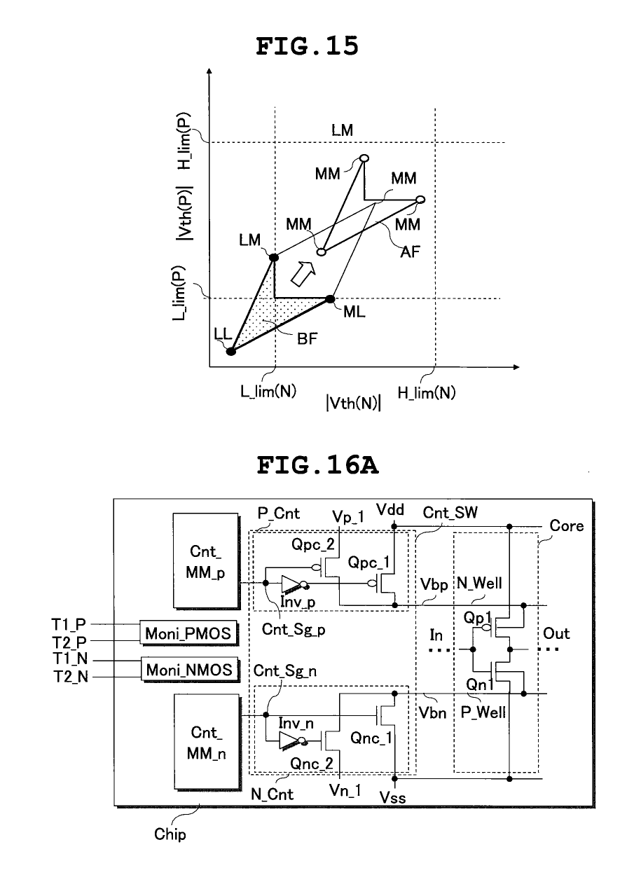

Therefore, in the further another concrete embodiment, each of independent variations in the threshold voltages in the pMOS and nMOS transistors in the CMOS circuit can be compensated independently (refer to FIG. 15).

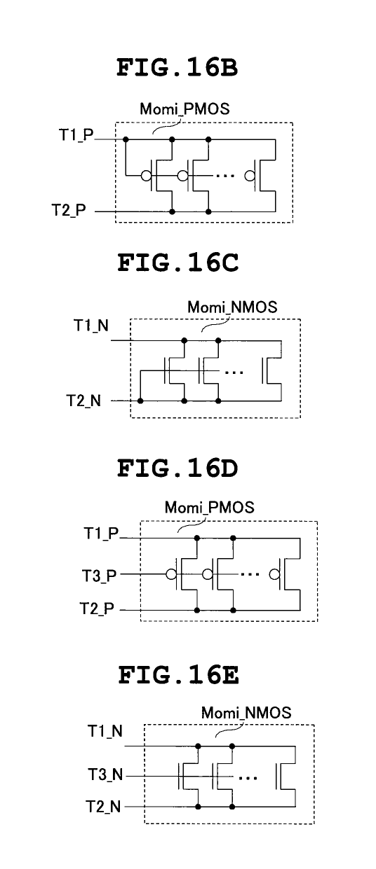

A semiconductor integrated circuit as a further another concrete embodiment includes, in a chip, a monitor pMOS transistor (Moni_pMOS) and a monitor nMOS transistor (Moni_NMOS) for evaluating a pMOS leakage current characteristic in the pMOS transistor and an nMOS leakage current characteristic in the nMOS transistor in the CMOS circuit (refer to FIG. 16).

Therefore, according to the further another concrete embodiment, evaluation of the pMOS leakage current characteristic and the nMOS leakage current characteristic can be facilitated.

A semiconductor integrated circuit as further another concrete embodiment includes, in a chip, a first sense circuit (Idd_Sense) for sensing a leakage current characteristic of the pMOS transistor in the CMOS circuit, a second sense circuit (Iss_Sense) for sensing a leakage current characteristic of the nMOS transistor in the CMOS circuit, and a control unit (Cont). In the case where measured leakage current in the pMOS and nMOS transistors changes from a past value by a predetermined allowable range or more, the control unit stores new control information into the control memory (refer to FIG. 26).

Therefore, as the further another concrete embodiment, fluctuations in the threshold voltages of the pMOS and nMOS transistors in the core CMOS logic circuit “Core” with time due to severe stress of long time of an LSI can be compensated.

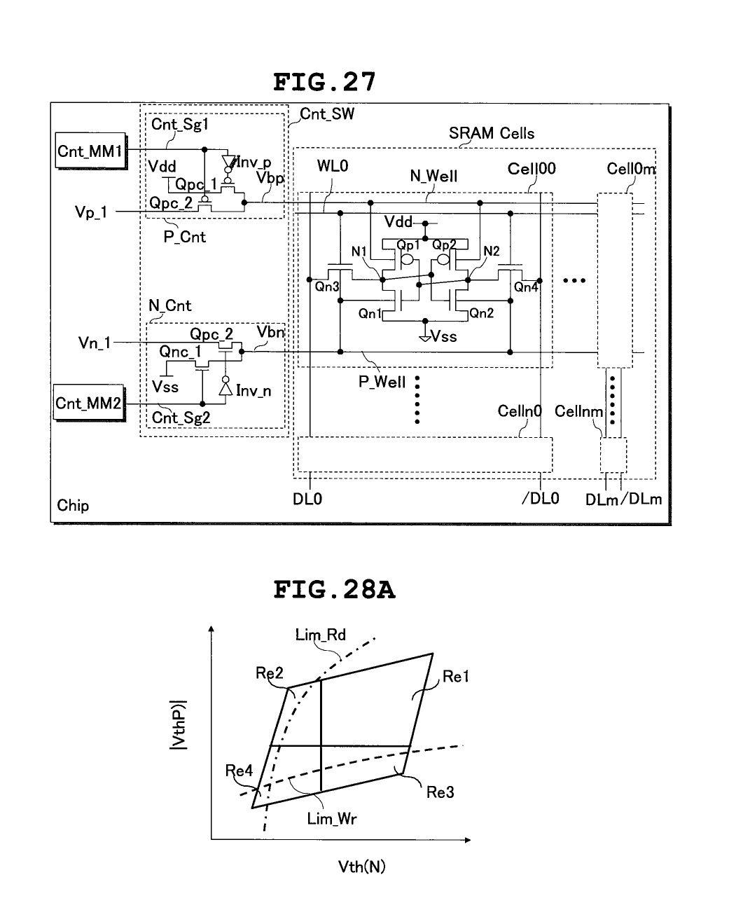

In a semiconductor integrated circuit as another more preferred embodiment, the CMOS circuit for processing the input signal is a logic circuit. The semiconductor integrated circuit includes, in a chip, the CMOS circuit as the logic circuit and a CMOS-embedded SRAM. A memory cell in the CMOS-embedded SRAM includes a pair of driver nMOS transistors (Qn1, Qn2), a pair of load pMOS transistors (Qp1, Qp2), and a pair of transfer nMOS transistors (Qn3, Qn4). The semiconductor integrated circuit further includes a control switch (Cnt_SW) for a embedded SRAM, for supplying a pMOS body bias voltage for the embedded SRAM and an nMOS body bias voltage for the embedded SRAM to N wells in a plurality of pMOS transistors (Qp1, Qp2) and P wells in a plurality of nMOS transistors (Qn1, Qn2, Qn3, and Qn4), respectively, in the CMOS-embedded SRAM. The semiconductor integrated circuit further includes a control memory (Cnt_MM1 and Cnt_MM2) for the embedded SRAM for storing control information (Cnt_Sg1 and Cnt_Sg2) for the embedded SRAM, indicating whether or not the pMOS body bias voltage for the embedded SRAM and the nMOS body bias voltage for the embedded SRAM are supplied from the control switch for the embedded SRAM to the N wells in the pMOS transistors and the P wells in the nMOS transistors, respectively, in the CMOS-embedded SRAM (refer to FIG. 27).

Therefore, in the further another preferred embodiment, the embedded SRAM can be manufactured at high manufacture yield, and variations in the threshold voltages of the driver nMOS transistor, the load pMOS transistor, and the transfer nMOS transistor causing an error in the reading and writing operations of the embedded SRAM can be compensated.

In a semiconductor integrated circuit as further another more preferred embodiment, the pMOS transistor in the CMOS circuit is a pMOS transistor of an SOI structure. The nMOS transistor in the CMOS circuit is an nMOS transistor of the SOI structure. A source and a drain of the pMOS transistor and a source and a drain of the nMOS transistor are formed in silicon over an insulating film in the SOI structure. The N well (N_Well) in the pMOS transistor and the P well (P_Well) in the nMOS transistor are formed in a silicon substrate (P_Sub) below the insulating film having the SOI structure (refer to FIG. 32).

Therefore, in the further another preferred embodiment, the capacitance between the drain and the well can be reduced, and the high-speed low-power-consumption semiconductor integrated circuit can be provided.
[2] A semiconductor integrated circuit according to another aspect includes a MOS circuit (Core) for processing an input signal (In) in an active mode. The semiconductor integrated circuit further includes a control switch (Cnt_SW) for supplying a MOS body bias voltage (Vbn) to a well (P_Well) in a MOS transistor (Qn1) in the MOS circuit. The semiconductor integrated circuit includes a control memory (Cnt_MM) for storing control information (Cnt_Sg) indicating whether or not the MOS body bias voltage is supplied from the control switch to the well in the MOS transistor in the MOS circuit at least in the active mode (refer to FIG. 1).

In such a manner, according to the embodiment, high manufacture yield can be achieved and variations in the threshold voltages of the MOS transistors can be compensated with small overhead.

In the semiconductor integrated circuit as a preferred embodiment, the control memory is a nonvolatile memory. Information determining whether the threshold voltage of the MOS transistor in the MOS circuit is low or not can be stored in the nonvolatile memory as the control memory (refer to FIGS. 2, 3, 4, 8, and 9).

Therefore, in the preferred embodiment, only by executing the determination to see whether the threshold voltage of the MOS transistor in the MOS circuit is low or not once, variations in the threshold voltage in the MOS transistor in the MOS circuit can be compensated.

In a semiconductor integrated circuit in a more preferred embodiment, an operation voltage is supplied to a source of the MOS transistor in the MOS circuit. The semiconductor integrated circuit includes a voltage generator for generating the MOS body bias voltage higher than the operation voltage.

Therefore, in the more preferred embodiment, the MOS body bias voltage can be generated by the reduced number of operation voltage supply terminals.

In the semiconductor integrated circuit as a more preferred embodiment, the control switch applies a well standby voltage higher than the MOS body bias voltage as a reverse body bias of the operation voltage to the well in the MOS transistor in a standby mode (refer to FIG. 11).

Therefore, in the more preferred embodiment, the standby leakage current of the MOS transistor in the MOS circuit can be largely reduced in the standby mode.

In the semiconductor integrated circuit as a concrete embodiment, an operation voltage is supplied to a source of the MOS transistor in the MOS circuit. The MOS body bias voltage supplied to the well is set as a reverse body bias of the operation voltage supplied to the source of the MOS transistor in the MOS circuit. By supplying the MOS body bias voltage set to a level higher than the operation voltage to the well, the MOS transistor having the well is controlled in a state of a high threshold voltage and a low leakage current (refer to FIGS. 4A and 4B).

In the semiconductor integrated circuit as further another concrete embodiment, an operation voltage is supplied to a source of the MOS transistor in the MOS circuit. The MOS body bias voltage supplied to the well is set as a forward body bias of the operation voltage supplied to the source of the MOS transistor in the MOS circuit. By supplying the MOS body bias voltage set to a level lower than the operation voltage to the well, the MOS transistor having the well is controlled in a state of a low threshold voltage and a high leakage current (refer to FIGS. 24A and 24B).

In the semiconductor integrated circuit as further another concrete embodiment, a monitor MOS transistor for evaluating a leakage current characteristic of the MOS transistor in the MOS circuit is included in a chip (refer to FIG. 16).

Therefore, in the further another concrete embodiment, evaluation of the MOS leakage current characteristic can be facilitated.

In the semiconductor integrated circuit as further another concrete embodiment, a sense circuit for sensing a leakage current characteristic of the MOS transistor in the MOS circuit and a control unit are included in a chip. In the case where measured leakage current in the MOS transistor changes from a past value by a predetermined allowable range or more, the control unit stores new control information into the control memory (refer to FIG. 26).

Therefore, in the further another concrete embodiment, fluctuations in the threshold voltages of the MOS transistors in the core MOS logic circuit “Core” with time due to severer stress for long time of the LSI can be compensated.

In the semiconductor integrated circuit as further another more preferred embodiment, the MOS transistor in the MOS circuit is aMOS transistor of an SOI structure. A source and a drain of the MOS transistor are formed in silicon over an insulating film in the SOI structure. The well (P_Well) in the MOS transistor is formed in a silicon substrate (P_Sub) below the insulating film having the SOI structure (refer to FIG. 32).

Therefore, in the further another more preferred embodiment, the capacitance between the drain and the well can be reduced, and the high-speed low-power-consumption semiconductor integrated circuit can be provided.
[3]

A method of manufacturing a semiconductor integrated circuit as another embodiment of the invention includes a step of preparing a wafer including a chip (“Chip”) of a semiconductor integrated circuit having therein a CMOS circuit (Core), a control switch (Cnt_SW), and a control memory (Cnt_MM) (step 91 in FIG. 9). The CMOS circuit processes an input signal (In) in an active mode. The control switch supplies a pMOS body bias voltage (Vbp) and an nMOS body bias voltage (Vbn) to an N well (N_Well) in a pMOS transistor (Qp1) and a P well (P_Well) in an nMOS transistor (Qn1), respectively, in the CMOS circuit. The control memory is a nonvolatile memory for storing, in a nonvolatile manner, control information (Cnt_Sg) indicating whether or not the pMOS body bias voltage and the nMOS body bias voltage are supplied from the control switch to the N well in the pMOS transistor and the P well in the nMOS transistor, respectively, in the CMOS circuit at least in the active mode.

The manufacturing method includes the step of measuring at least one of threshold voltages of the pMOS transistor and the nMOS transistor in the CMOS circuit (step 92 in FIG. 9).

The manufacturing method includes a step of determining whether the measured threshold voltage is lower than a target or not (step 93 in FIG. 9).

The manufacturing method includes a step of storing, in a nonvolatile manner, a result of the determination as the control information into the control memory (step 94 in FIG. 9).

In the method of manufacturing a semiconductor integrated circuit as a preferred embodiment, the CMOS circuit for processing the input signal is a logic circuit. The semiconductor integrated circuit includes, in a chip, the CMOS circuit as the logic circuit and a CMOS-embedded SRAM. A memory cell in the CMOS-embedded SRAM includes a pair of driver nMOS transistors (Qn1, Qn2), a pair of load pMOS transistors (Qp1, Qp2), and a pair of transfer nMOS transistors (Qn3, Qn4). The semiconductor integrated circuit further includes: a control switch (Cnt_SW) for a embedded SRAM, for supplying a pMOS body bias voltage for the embedded SRAM and an nMOS body bias voltage for the embedded SRAM to N wells in a plurality of pMOS transistors (Qp1, Qp2) and P wells in a plurality of nMOS transistors (Qn1, Qn2, Qn3, and Qn4), respectively, in the CMOS-embedded SRAM. The semiconductor integrated circuit further includes a control memory (Cnt_MM1, Cnt_MM2) for the embedded SRAM for storing, in a nonvolatile manner, control information (Cnt_Sg1, Cnt_Sg2) for the embedded SRAM, indicating whether or not the pMOS body bias voltage for the embedded SRAM and the nMOS body bias voltage for the embedded SRAM are supplied from the control switch for the embedded SRAM to the N wells in the pMOS transistors and the P wells in the nMOS transistors, respectively, in the CMOS-embedded SRAM (refer to FIG. 27).

In the manufacturing method, threshold voltages of the pMOS transistor and the nMOS transistor in the CMOS-embedded SRAM are measured, whether the measured threshold voltage is lower than a target or not is determined, and a result of the determination is stored as the control information for the embedded-SRAM into the control memory for the embedded-SRAM in a nonvolatile manner (refer to FIGS. 27, 28, 29, and 30).

### Description of Embodiments

Embodiments will be described in more details.

### <<Configuration of Semiconductor Integrated Circuit>>

FIG. 1 is a circuit diagram showing a semiconductor integrated circuit as an embodiment of the present invention capable of compensating variations among LSI chips by a bias control on a well in a substrate of a MOS transistor.

In the diagram, an LSI as a semiconductor integrated circuit as an embodiment of the invention includes a CMOS logic circuit of a core circuit “Core” and includes a control memory Cnt_MM and a control switch Cnt_SW for compensating variations in the characteristic of the core CMOS logic circuit “Core”. The core CMOS logic circuit “Core” includes a pMOS Qp1 whose source is connected to the power source voltage Vdd and an nMOS Qn1 whose source is connected to the ground voltage Vss. An input signal In is applied to the gate of the pMOS Qp1 and the nMOS Qn1, and an output signal Out is obtained from the drain of the pMOS Qp1 and the drain of the nMOS Qn1. The control switch Cnt_SW includes a pMOS controller P_CNT and an nMOS controller N_CNT.

The pMOS controller P_Cnt is constructed by a pMOS Qpc_1, a pMOS Qpc_2, and an inverter Inv_p. In the pMOS controller P_Cnt, the power source voltage Vdd is applied to the source of the pMOS Qpc_1, and an N-well bias voltage Vp_1 higher than the power source voltage Vdd is applied to the source of the pMOS Qpc_2. The drain of the pMOS Qpc_1 and the drain of the pMOS Qpc_2 are connected to an N well N_Well of the pMOS Qp1 in the core CMOS logic circuit “Core”.

The nMOS controller N_Cnt is constructed by an nMOS Qnc_1, an nMOS Qnc_2, and an inverter Inv-n. In the nMOS controller N_Cnt, the ground voltage Vss is applied to the source of the nMOS Qnc_1, and a P-well bias voltage Vn_1 lower than the ground voltage Vss is applied to the source of the nMOS Qnc_2. The drain of the nMOS Qnc_1 and the drain of the nMOS Qnc_2 are connected to a P well P_Well of the nMOS Qn1 in the core CMOS logic circuit “Core”.

When an output signal Cnt_Sg of the control memory Cnt_MM becomes the high level, the pMOS Qpc_1 of the pMOS controller P_Cnt is turned on, and the nMOS Qnc_1 of the nMOS controller N_Cnt is turned on. The power source voltage Vdd is applied as a pMOS body bias voltage Vbp to the N well N-Well of the pMOS Qp1 in the core CMOS logic circuit “Core”, and the ground voltage Vss is applied as the nMOS body bias voltage Vbn to the P well P_WELL of the nMOS Qn1 of the core CMOS logic circuit “Core”. On the other hand, the power source voltage Vdd and the ground voltage Vss are supplied to the source of the pMOS Qp1 and the source of the mMOS Qn1, respectively, of the core CMOS logic circuit “Core”. Therefore, the power source voltage Vdd is commonly applied to the source of the pMOS Qp1 and the N well N_Well in the core MOS logic circuit “Core”, and the ground voltage Vss is commonly applied to the source of the nMOS Qn1 and the P-well P_Well in the core MOS logic circuit “Core”.

When the output signal Cnt_Sg of the control memory Cnt_MM becomes the low level, the pMOS Qpc_2 of the pMOS controller P_Cnt is turned on, and the nMOS Qnc_2 of the nMOS controller N_Cnt is turned on. The N-well bias voltage Vp_1 higher than the power source voltage Vdd is applied as a pMOS body bias voltage Vbp to the N well N_Well of the pMOS Qp1 in the core CMOS logic circuit “Core”. The P-well bias voltage Vn_1 lower than the ground voltage Vss is applied as the nMOS body bias voltage Vbn to the P well P_WELL of the nMOS Qn1 of the core CMOS logic circuit “Core”. On the other hand, the power source voltage Vdd and the ground voltage Vss are supplied to the source of the pMOS Qp1 and the source of the nMOS Qn1, respectively, of the core CMOS logic circuit “Core”. Therefore, the N-well bias voltage Vp_1 applied to the N well N_Well is reverse bias of the power source voltage Vdd applied to the source of the pMOS Qp1 in the core MOS logic circuit “Core”. The low P-well bias voltage Vn_1 applied to the P-well P_Well is also the reverse bias of the ground voltage Vss applied to the source of the nMOS Qn1 of the core CMOS logic circuit “Core”. As a result, both of the pMOS Qp1 and the nMOS Qn1 of the core CMOS logic circuit “Core” are controlled by the high threshold voltage Vth, and the leakage current can be reduced.

### <<Wafer Test and Wafer Process for Measuring Leakage Current>>

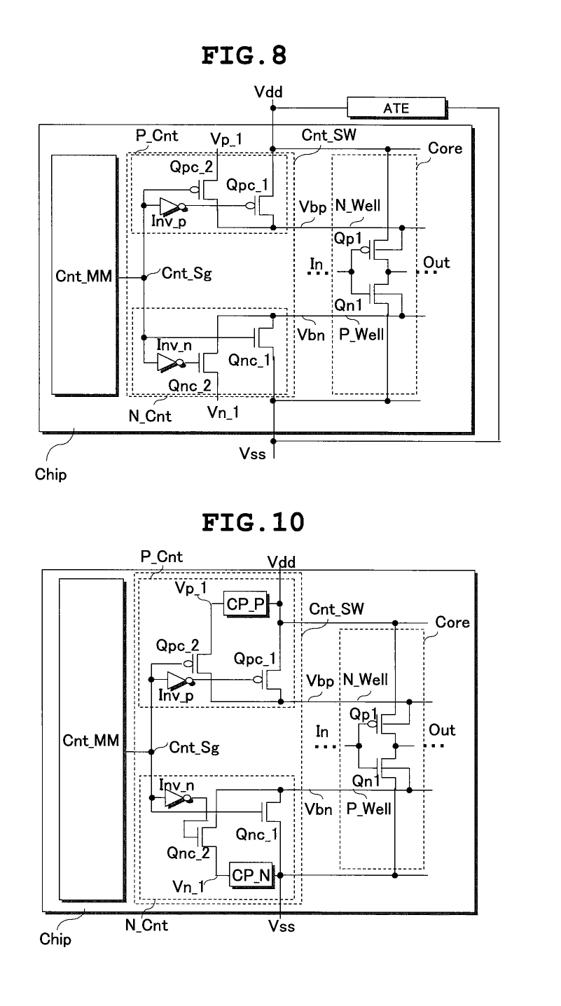

FIG. 8 is a diagram showing a test of a wafer including a number of LSI chips illustrated in FIG. 1. FIG. 9 is a diagram illustrating a method of manufacturing a semiconductor integrated circuit, including the flow of a wafer test and a wafer process.

First, when the wafer test is started in step 91 in FIG. 9, leakage current in one LSI chip “Chip” is measured by an external tester ATE shown in FIG. 8 connected in advance to the power source voltage Vdd and the ground voltage Vss of the LSI chip “Chip” in step 92 of current measurement. In the following determination step 93, whether the leakage current measured in the step 92 is larger than a nominal value or not is determined by the external tester ATE. When the external tester ATE determines that the leakage current measured in the determination step 93 is larger than the nominal value, it means that the threshold voltage Vth of the MOS transistor in the core CMOS logic circuit “Core” of the chip “Chip” is much smaller than the nominal value. In this case, to change the threshold voltage Vth of the MOS transistor in the core CMOS logic circuit “Core” from low Vth to high Vth, in the following step 94, a fuse FS as a nonvolatile memory of the control memory Cnt_MM is opened to apply the body bias. On the contrary, when the external tester ATE determines that the leakage current measured in the determination step 93 is smaller than the nominal value, it means that the threshold voltage Vth of the MOS transistor in the core CMOS logic circuit “Core” of the chip “Chip” is higher than the nominal value. In this case, it is unnecessary to change the threshold voltage Vth of the MOS transistor in the core CMOS logic circuit “Core” to high Vth, the process is finished in step 95, and the program moves to the processes in the step 92 of measuring the leakage current in the next LSI chip “Chip” and the determination step 93.

After the test of the LSI wafer including the number of chips shown in FIG. 9 is completed, the fuse FS in the control memory Cnt_MM in each of the number of chips of the single wafer is in a cut state or a not-cut state. The operation in the case where the fuse FS in the control memory Cnt_MM is cut and that in the case where the fuse FS is not cut in the LSI chip “Chip” shown in FIG. 1 will be described.

### <<Control Memory>>

FIGS. 2A and 2B are circuit diagrams showing an example of the configuration of the control memory Cnt_MM of the LSI chip “Chip” illustrated in FIG. 1. FIG. 2A shows the simplest control memory Cnt_MM which is constructed by the fuse FS and a resistor R connected in series between the power source voltage Vdd and the ground voltage GND. FIG. 2B shows a slightly complicated control memory Cnt_MM. The control memory Cnt_MM is constructed by a pMOS Qmp_1, a fuse FS, a resistor R, and an nMOS Qmn_1 which are connected in series between the power source voltage Vdd and the ground voltage GND, four inverters Inv_m1 to Inv_m4, and a CMOS analog switch SW_m1. In the case of cutting the fuse FS in the control memory Cnt_MM in FIG. 2A in step 94 in FIG. 9, the fuse FS is cut by application of the high power source voltage Vdd for cut. In the case of cutting the fuse FS in the control memory Cnt_MM in FIG. 2B in step 94 in FIG. 9, by applying a high-level start signal St and also the high power source voltage Vdd for cut, the fuse FS is cut. When the fuse FS in the control memory Cnt_MM in FIG. 2A is cut in step 94 in FIG. 9, the output signal Cnt_SG of the control memory Cnt_MM on start of the operation of the LSI chip “Chip” becomes the low-level ground voltage GND. On the contrary, when the fuse FS in the control memory Cnt_MM in FIG. 2A is not cut in the flow of FIG. 9, the output signal Cnt_Sg on start of the operation of the LSI chip “Chip” becomes the high-level power source voltage Vdd. When the fuse FS of the control memory Cnt_MM in FIG. 2B is cut in the flow of FIG. 9, in response to the high-level start signal St, a latch output signal Cnt_Sg of the control memory Cnt_MM on start of the operation becomes the low-level ground voltage GND. On the contrary, when the fuse FS in the control memory Cnt_MM in FIG. 2B is not cut in the flow of FIG. 9, the latch output signal Cnt_Sg on start of the operation becomes the high-level power source voltage Vdd in response to the high-level start signal St.

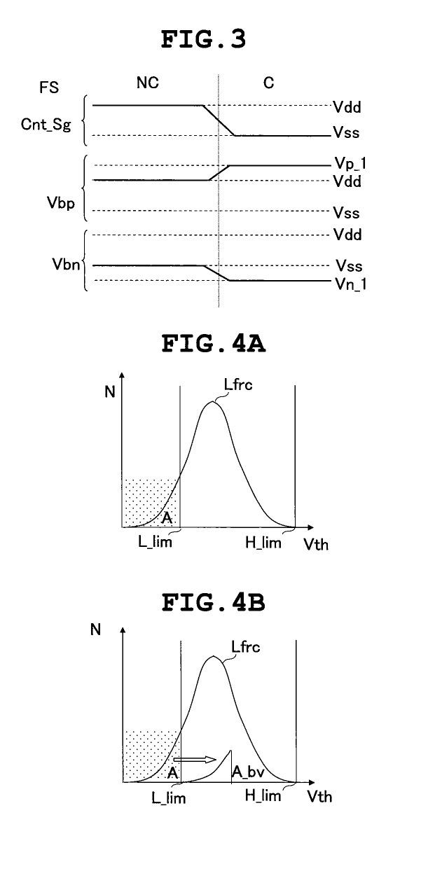

It is assumed that the fuse FS in the control memory Cnt_MM in the LSI chip “Chip” shown in FIG. 1 is in a not-cut state. The latch output signal Cnt_Sg of the control memory Cnt_MM on start of the operation of the LSI chip “Chip” is the high-level power source voltage Vdd. First, in the pMOS controller P_Cnt of the control switch Cnt_SW, the pMOS Qpc_2 is turned off, an output of the inverter Inv_p becomes the low level, and the pMOS Qpc_1 is turned on. By turn-on of the pMOS Qpc_1, to the N well N_Well of the pMOS Qp1 in the core CMOS logic circuit “Core”, the power source voltage Vdd applied to the source of the pMOS Qpc_1 is applied. In the nMOS controller N_Cnt in the control switch Cnt_SW, the nMOS Qnc_1 is turned on, the output of the inverter Inv_n becomes the low level, and the nMOS Qnc_2 is turned off. By turn-on of the nMOS Qnc_1, to the P well P_Well of the nMOS Qn1 in the core CMOS logic circuit “Core”, the ground voltage Vss applied to the source of the nMOS Qn1 of the pMOS is applied. The relations of the voltages in the parts of the semiconductor integrated circuit shown in FIG. 1 at this time are shown in the not-cut state NC in the left part of FIG. 3. FIG. 3 is a diagram showing the relations of the voltages in the parts of the semiconductor integrated circuit illustrated in FIG. 1.

It is assumed that the fuse FS in the control memory Cnt_MM in the LSI chip “Chip” shown in FIG. 1 is in a cut state. The latch output signal Cnt_Sg of the control memory Cnt_MM on start of the operation of the LSI chip “Chip” is the low-level ground voltage Vss. First, in the pMOS controller P_Cnt of the control switch Cnt_SW, the pMOS Qpc_2 is turned on, an output of the inverter Inv_p becomes the high level, and the pMOS Qpc_1 is turned off. By turn-on of the pMOS Qpc_2, to the N well N_Well of the pMOS Qp1 in the core CMOS logic circuit “Core”, the high N-well bias voltage Vp_1 applied to the source of the pMOS Qpc_2 is applied. In the nMOS controller N_Cnt in the control switch Cnt_SW, the nMOS Qnc_1 is turned off, the output of the inverter Inv_n becomes the high level, and the nMOS Qnc-2 is turned on. By turn-on of the nMOS Qnc_2, to the P well P_Well of the nMOS Qn1 in the core CMOS logic circuit “Core”, the low P-well bias voltage Vn_1 applied to the source of the nMOS Qn2 is applied. The relations of the voltages in the parts of the semiconductor integrated circuit shown in FIG. 1 at this time are shown in the cut state C in the right part of FIG. 3. As described above, the high N-well bias voltage Vp_1 is applied to the N well N_Well of the pMOS Qp1 in the core CMOS logic circuit “Core”, and the low P-well bias voltage Vn_1 is applied to the P well P_Well of the nMOS Qn1 in the core CMOS logic circuit “Core”. As shown in FIG. 3, the N-well bias voltage Vp_1 of the pMOS Qp1 is set to be higher than the power source voltage Vdd of the source, and the P-well bias voltage Vn_1 of the nMOS Qn1 is set to be lower than the ground voltage Vss of the source. As a result, the threshold voltage of the pMOS Qp1 and the nMOS Qn1 in the core CMOS logic circuit “Core” is changed from the low Vth to the high Vth.

### <<Control on Threshold Voltage Vth of MOS LSI>>

FIGS. 4A and 4B show distributions of the threshold voltage Vth of the manufactured MOS LSI. The horizontal axis of each of the diagrams shows the threshold voltage Vth of the MOS LSI, and the longitudinal axis of the diagram shows the number of MOS LSI chips, and a curve Lfrc denotes the distribution. When the threshold voltage Vth of the MOS LSI decreases to a lower threshold value L_lim or less, the leakage current increases remarkably, and current consumption becomes excessive. On the contrary, when the threshold voltage Vth of the MOS LSI increases to an upper limit threshold value H_lim or higher, switching speed drops markedly, and data processing speed also drops markedly.

Therefore, a group A of MOS LSI chips existing at the lower limit threshold value L_lim or less in FIG. 4A is discarded as defectives before the present invention. In one embodiment of the present invention, in the group A of MOS LSI chips, the fuse is cut out in step 94 in FIG. 9. By the operation, the threshold voltage of the pMOS Qp1 and the nMOS Qn1 in the core CMOS logic circuit “Core” changes from the low Vth to the high Vth on start of the operation of the LSI chip “Chip”, and the chip group A changes to a reproduced chip group A_bv as shown in FIG. 4B. As a result, the average threshold voltage Vth of all of pMOS and all of nMOS in the core CMOS logic circuit of the MOS LSI chip increases to the lower limit threshold value L_lim or higher, and the leakage current in the whole chip can be reduced.

In the semiconductor integrated circuit as an embodiment of the invention, by adding the control memory Cnt_MM and the control switch Cnt_SW having a small occupation area to the core CMOS logic circuit of a large-scale logic occupying a large area in the LSI chip, the MOS LSI realizing low leakage current can be manufactured with high manufacture yield.

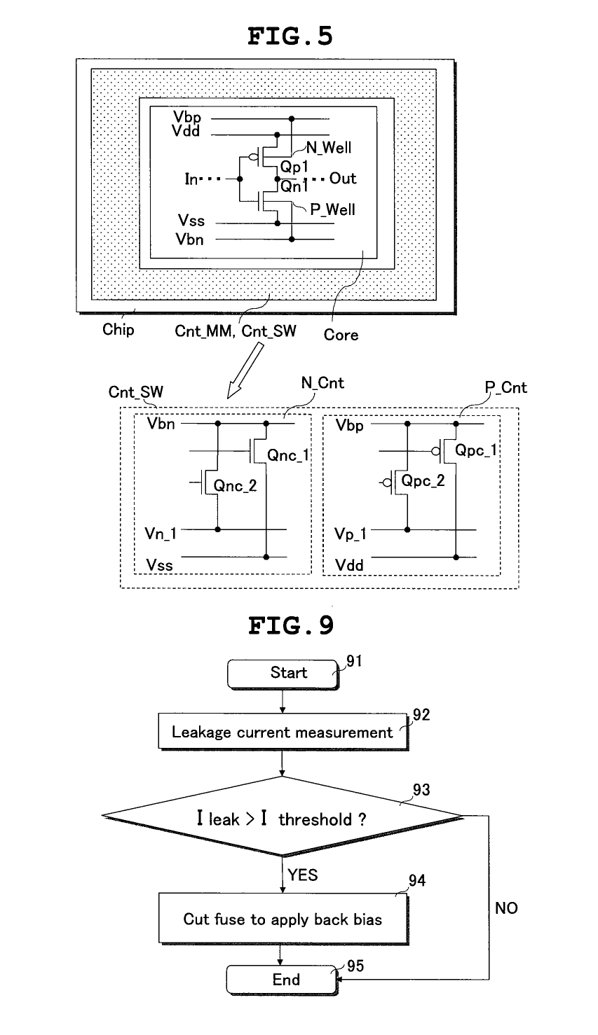

FIG. 5 is a diagram showing the layout in which the control memory Cnt_MM and the control switch Cnt_SW of small occupation area overhead are disposed around the core CMOS logic circuit “Core” in the LSI chip. In particular, it is recommended to dispose a plurality of nMOS controller N_Cnt and a plurality of pMOS controllers P_Cnt in the control switch Cnt_SW so as to be dispersed around the core CMOS logic circuit “Core”.

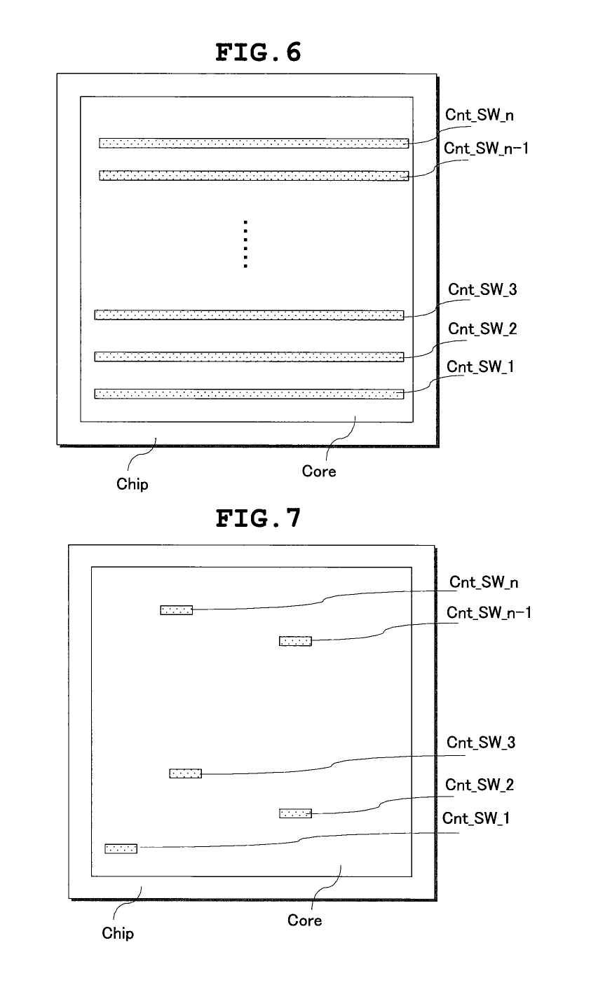

FIG. 6 is a diagram showing a layout in which a plurality of control switches Cnt_SW_1, . . . Cnt_SW_n each corresponding to the control switch Cnt_SW in FIG. 1 are disposed in the core CMOS logic circuit “Core” in the LSI chip. In FIG. 6, the control switches Cnt_SW_1, . . . Cnt_SW_n have almost equal lengths and are regularly disposed in the core CMOS logic circuit “Core”.

FIG. 7 is a diagram showing another layout in which a plurality of control switches Cnt_SW_1, . . . Cnt_SW_n each corresponding to the control switch Cnt_SW in FIG. 1 are disposed in the core CMOS logic circuit “Core” in the LSI chip. As shown in FIG. 7, the control switches Cnt_SW_1, . . . Cnt_SW_n may have different lengths and are irregularly disposed in the core CMOS logic circuit “Core”.

### Other Embodiments

### <<On-Chip Voltage Generator>>

FIG. 10 is a circuit diagram showing a semiconductor integrated circuit as another embodiment of the invention. A MOS LSI chip “Chip” shown in FIG. 10 is different from the MOS LSI chip “Chip” shown in FIG. 1 with respect to the point that the pMOS controller P_Cnt and the nMOS controller N_Cnt in the control switch Cnt_SW include a positive voltage generator CP_P and a negative voltage generator CP_N, respectively. The other parts of the semiconductor integrated circuit of FIG. 10 are the same as those of the semiconductor integrated circuit shown in FIG. 1.

First, on the basis of the power source voltage Vdd supplied to the MOS LSI chip “Chip”, the positive voltage generator CP_P of the pMOS controller P_Cnt in the control switch Cnt_SW generates an N-well bias voltage Vp_1 higher than the power source voltage Vdd. The generated high N-well bias voltage Vp_1 is supplied to the N well N_Well of the pMOS Qp1 in the core CMOS logic circuit “Core”. On the basis of the ground voltage Vss supplied to the MOS LSI chip “Chip”, the negative voltage generator CP_N in the nMOS controller N_Cnt in the control switch Cnt_SW generates the P-well bias voltage Vn_1 lower than the ground voltage Vss. The generated low P-well bias voltage Vn_1 is supplied to the P well P_Well of the nMOS Qn1 in the core CMOS logic circuit Core. As a result, the number of external terminals of the MOS LSI chip “Chip” shown in FIG. 10 can be reduced more than that of the MOS LSI chip “Chip” shown in FIG. 1. Each of the positive voltage generator CP_P and the negative voltage generator CP_N can be constructed by a charge pump. It can be also constructed by a DC/DC converter made by a switching regulator or the like.

### <<Standby Control>>

FIG. 11 is a circuit diagram showing a semiconductor integrated circuit as further another embodiment of the invention. A MOS LSI chip “Chip” shown in FIG. 11 basically differs from the MOS LSI chip “Chip” shown in FIG. 1 with respect to the point that the pMOS controller P_Cnt and the nMOS controller N_Cnt in the control switch Cnt_SW are controlled by a standby control signal Stby from the outside of the chip. Further, an N-well standby voltage Vp_stby higher than the N-well bias voltage Vp_1 is applied to the source of the pMOS Qpc_3 in the pMOS controller P_Cnt. A P-well standby voltage Vn_stby lower than the P-well bias voltage Vn_1 is applied to the source of the nMOS Qnc_3 of the nMOS controller N_Cnt. The other parts of the semiconductor integrated circuit of FIG. 11 are the same as those of the semiconductor integrated circuit shown in FIG. 1.

In the case of reducing standby leakage current of the pMOS Qp1 and the nMOS Qn1 of the core CMOS logic circuit “Core” in a non-operation period of the core CMOS logic circuit “Core”, the high-level standby control signal Stby is applied from the outside of the chip. Since an output of the inverter Inv_p1 of the pMOS controller P_Cnt becomes the low level in response to the high-level standby control signal Stby, outputs of the NAND circuits NAND_p1 and NAND_p2 become the high level. The pMOS Qpc_1 and Qpc_2 of the pMOS controller P_Cnt are turned off and the pMOS Qpc_3 is turned on. Consequently, the N-well standby voltage Vp_stby higher than the N-well bias voltage Vp_1 is applied to the N well N_Well of the pMOS Qp1 in the core CMOS logic circuit “Core”. Therefore, the threshold voltage of the pMOS Qp1 in the core CMOS logic circuit “Core” becomes Vth of a very high level, and standby leakage current in the pMOS Qp1 can be largely reduced. In response to the high-level standby control signal Stby, outputs of NOR circuits NOR_n1 and NOR_n2 in the nMOS controller N_Cnt become the low level, the nMOS Qnc_1 and Qnc_2 of the nMOS controller N_Cnt are turned off, and the nMOS Qnc_3 is turned on. Therefore, to the P well P_Well of the nMOS Qn1 in the core CMOS logic circuit “Core”, the P-well standby voltage Vn_stby lower than the P-well bias voltage Vn_1 is applied. Thus, the threshold voltage of the nMOS Qn1 in the core CMOS logic circuit “Core” becomes Vth of a very high level, and the standby leakage current in the nMOS Qn1 can be largely reduced.

### <<Control on Plural Cores>>

FIG. 12 is a circuit diagram showing a semiconductor integrated circuit of further another embodiment of the present invention. A MOS LSI chip “Chip” shown in FIG. 12 basically differs from the MOS LSI chip “Chip” shown in FIG. 1 with respect to the point that the core CMOS logic circuit is constructed by a plurality of core CMOS logic circuits Core1 and Core2. Accordingly, the control memory is also constructed by a plurality of control memories Cnt_MM1 and Cnt_MM2. The pMOS controller in the control switch Cnt_SW is also constructed by a plurality of pMOS controllers P_Cnt1 and P_Cnt2. The nMOS controller in the control switch Cnt_SW is also constructed by a plurality of nMOS controllers N_Cnt1 and N_Cnt2. The other parts of the semiconductor integrated circuit of FIG. 12 are the same as those of the semiconductor integrated circuit shown in FIG. 1.

Therefore, by setting output signals Cnt_Sg1 and Cnt_Sg2 of the control memories Cnt_MM1 and Cnt_MM2 at different levels, one of the core CMOS logic circuits Core1 and Core2 is controlled to have characteristics of high Vth, low leakage current, and low power consumption, and the other is controlled to have characteristics of low Vth, high leakage current, and very-high-speed operation.

By measuring the leakage currents of the core CMOS logic circuits Core1 and Core2 and cut the fuse FS in the control memory of the CMOS logic circuit having larger leakage current, the core CMOS logic circuit can be changed to have characteristics of high Vth, low leakage current, and low power consumption.

### <<Plural Well Bias Voltages>>

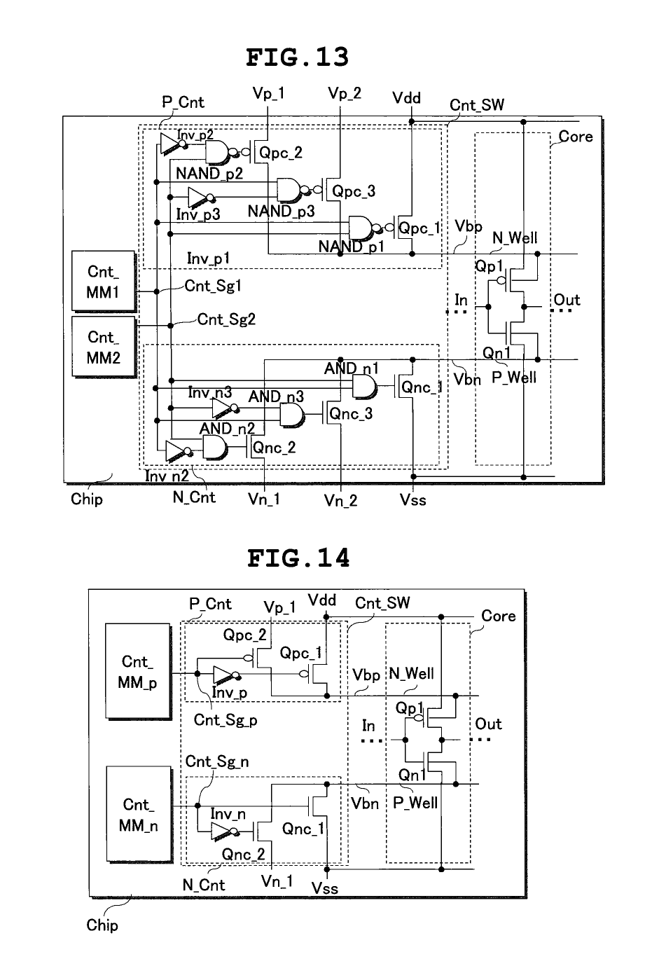

FIG. 13 is a circuit diagram showing a semiconductor integrated circuit of further another embodiment of the present invention. A MOS LSI chip “Chip” shown in FIG. 13 basically differs from the MOS LSI chip “Chip” shown in FIG. 1 with respect to the point that a well bias voltage can be selected from a plurality of well bias voltages as each of the high well bias voltage applied to the N well in the pMOS in the core CMOS logic circuit “Core” and the low well bias voltage applied to the P well in the nMOS. Accordingly, the control memory is also constructed by the control memories Cnt_MM1 and Cnt_MM2. The other parts of the semiconductor integrated circuit in FIG. 13 are the same as those of the semiconductor integrated circuit shown in FIG. 1.

To the pMOS controller P_Cnt in the control switch Cnt_SW, the power source voltage Vdd, a first bias voltage Vp_1 slightly higher than the power source voltage Vdd, and a second bias voltage Vp_2 slightly higher than the first bias voltage Vp_1 are supplied. The power source voltage Vdd is applied to the source of the pMOS Qpc1, the N-well first bias voltage Vp_1 is applied to the source of the pMOS Qpc2, and the N-well second bias voltage Vp_2 is applied to the source of the pMOS Qpc3. The gate of the pMOS Qpc1 is controlled by a NAND circuit NAND_p1, the gate of the pMOS Qpc2 is controlled by an inverter Inv_p2 and a NAND circuit NAND_p2, and the gate of the pMOS Qpc3 is controlled by an inverter Inv_p3 and a NAND circuit NAND_p3.

To the nMOS controller N_Cnt in the control switch Cnt_SW, the ground voltage Vss, a first bias voltage Vn_1 slightly lower than the ground voltage Vss, and a second bias voltage Vn_2 slightly lower than the first bias voltage Vn_1 are supplied. The ground voltage Vss is applied to the source of the nMOS Qnc1, the P-well first bias voltage Vn_1 is applied to the source of the nMOS Qnc2, and the P-well second bias voltage Vn_2 is applied to the source of the nMOS Qnc3. The gate of the nMOS Qnc1 is controlled by an AND circuit AND_n1, the gate of the nMOS Qnc2 is controlled by an inverter Inv_n2 and an AND circuit AND_n2, and the gate of the nMOS Qnc3 is controlled by an inverter Inv_n3 and an AND circuit NAND_n3.

An output signal Cnt_Sg1 of the control memory Cnt_MM1 is supplied to the input of the inverter Inv_p2 and one of the inputs of each of the NAND circuits NAND_p1 and NAND_p3 in the pMOS controller P_Cnt. Similarly, the output signal Cnt_Sg1 of the control memory Cnt_MM1 is supplied to the input of the inverter Inv_n2 and one of the inputs of each of the AND circuits AND_n1 and AND_n3 in the nMOS controller N_Cnt. An output signal Cnt_Sg2 of the control memory Cnt_MM2 is supplied to the input of the inverter Inv_p3 and the other input of each of the NAND circuits NAND_p1 and NAND_p2 in the pMOS controller P_Cnt. Similarly, the output signal Cnt_Sg2 of the control memory Cnt_MM2 is supplied to the input of the inverter Inv_n3 and the other input of each of the AND circuits AND_n1 and AND_n2 in the nMOS controller N_Cnt.

Therefore, when the output signal Cnt_Sg1 of the control memory Cnt_MM1 is at the “1” level and the output signal Cnt_Sg2 of the control memory Cnt_MM2 is at the “1” level, the pMOS Qpc_1 in the pMOS controller P_Cnt is turned on, and the nMOS Qnc_1 in the nMOS controller N_cnt is turned on. Consequently, the power source voltage Vdd is applied to the N well in the pMOS Qp1 in the core CMOS logic circuit “Core” via Qpc_1 in the on state, and the ground voltage Vss is applied to the P well in the nMOS Qn1 in the core CMOS logic circuit “Core” via Qnc_1 in the on state.

When the output signal Cnt_Sg1 of the control memory Cnt_MM1 is at the “0” level and the output signal Cnt_Sg2 of the control memory Cnt_MM2 is at the “1” level, the pMOS Qpc_2 in the pMOS controller P_Cnt is turned on, and the nMOS Qnc_2 in the nMOS controller N_cnt is turned on. Consequently, the N-well first bias voltage Vp_1 is applied to the N well in the pMOS Qp1 in the core CMOS logic circuit “Core” via Qpc_2 in the on state, and the P-well first bias voltage Vn_1 is applied to the P well in the nMOS Qn1 in the core CMOS logic circuit “Core” via Qnc_2 in the on state. As a result, the threshold voltage of the core CMOS logic circuit “Core” can be changed to slightly higher Vth.

Further, when the output signal Cnt_Sg1 of the control memory Cnt_MM1 is at the “1” level and the output signal Cnt_Sg2 of the control memory Cnt_MM2 is at the “0” level, the pMOS Qpc_3 in the pMOS controller P_Cnt is turned on, and the nMOS Qnc_3 in the nMOS controller N_cnt is turned on. Consequently, the N-well second bias voltage Vp_2 is applied to the N well in the pMOS Qp1 in the core CMOS logic circuit “Core” via Qpc_3 in the on state, and the P-well second bias voltage Vn_2 is applied to the P well in the nMOS Qn1 in the core CMOS logic circuit “Core” via Qnc_3 in the on state. As a result, the threshold voltage of the core CMOS logic circuit “Core” can be changed to the highest Vth.

### <<Plural Control Memories>>

FIG. 14 is a circuit diagram showing a semiconductor integrated circuit of further another embodiment of the present invention. A MOS LSI chip “Chip” shown in FIG. 14 basically differs from the MOS LSI chip “Chip” shown in FIG. 1 with respect to the point that whether the well bias voltages Vp_1 and Vn_1 are applied to the pMOS Qp1 and the nMOS Qn1 in the core CMOS logic circuit or not can be set in control memories Cnt_MM_p and Cnt_MM_n. The other parts of the semiconductor integrated circuit of FIG. 14 are the same as those of the semiconductor integrated circuit shown in FIG. 1.

First, the advantage that whether or not the well bias voltages Vp_1 and Vn_1 are applied independently to the pMOS Qp1 and the nMOS Qn1 in the core CMOS logic circuit can be set will be described.

FIG. 15 is a diagram showing fluctuations in the electric characteristic of the core CMOS logic circuit due to variations in the nMOS threshold voltage Vth(N) and the absolute value |Vth(P)| of the pMOS threshold voltage in the core CMOS logic circuit. The horizontal axis of the diagram indicates the magnitude of the nMOS threshold voltage Vth(N) of the core CMOS logic circuit, and the vertical axis of the diagram shows the magnitude of the absolute value |Vth(P)| of the pMOS threshold voltage of the core CMOS logic circuit.

When the nMOS threshold voltage Vth(N) of the core CMOS logic circuit decreases to the lower limit value L_lim(N) or less on the horizontal axis of the diagram, the leakage current of the nMOS in the core CMOS logic circuit increases remarkably, and the current consumption of the LSI exceeds the design objective. On the other hand, when the nMOS threshold voltage Vth(N) of the core CMOS logic circuit increases to the upper limit value H_lim(N) or more on the horizontal axis of the diagram, delay time of the nMOS in the core CMOS logic circuit increases remarkably, and the operation speed of the LSI does not reach the design objective.

When the absolute value |Vth(P)| of the pMOS threshold voltage of the core CMOS logic circuit decreases to the lower limit value L_lim(P) or less on the horizontal axis of the diagram, the leakage current of the pMOS in the core CMOS logic circuit increases remarkably, and the current consumption of the LSI exceeds the design objective. On the other hand, the absolute value |Vth(P)| of the pMOS threshold voltage of the core CMOS logic circuit increases to the upper limit value H_lim(P) or more on the horizontal axis of the diagram, delay time of the pMOS in the core CMOS logic circuit increases remarkably, and the operation speed of the LSI does not reach the design objective.

In FIG. 15, a rhomboid having four apexes LL, ML, MM, and ML shows a distribution of variations in the nMOS threshold voltage Vth(N) and the absolute value |Vth(P)| of the pMOS threshold voltage in the core CMOS logic circuit. At the lower left apex LL, both of the nMOS threshold voltage Vth(N) and the absolute value |Vth(P)| of the pMOS threshold voltage in the core CMOS logic circuit are too low. At the apex ML on the line of the lower limit value L_lim(P), the nMOS threshold voltage Vth(N) exceeds the lower limit value L_lim(N) but the absolute value |Vth(P)| of the pMOS threshold voltage is just at the lower limit value L_lim(P). At the apex LM on the line of the lower limit value L_lim(N), the pMOS threshold voltage exceeds the lower limit value L_lim(P) but the nMOS threshold voltage Vth (N) is just at the lower limit value L_lim(N). At the upper right apex MM, both of the nMOS threshold voltage Vth(N) and the absolute value |Vth(P)| of the pMOS threshold voltage in the core CMOS logic circuit exceed the lower limit values L_lim(N) and L_lim(P), respectively.

Hitherto, a MOS LSI chip existing on the left side of the lower limit value L_lim(N) or in a part BF lower than the lower limit value L_lim(P) in the rhomboid having the four apexes LL, ML, MM, and ML shown in FIG. 15 is discarded as a defective having excessive leakage current. However, according to the further another embodiment of the invention shown in FIG. 14, the defective in the part BF can be changed to a regenerated chip AF by the two control memories Cnt_MM_p and Cnt_MM_n.

To be specific, the fuse in the control memory Cnt_MM_p for pMOS of a chip in which the absolute value |Vth(P)| of the pMOS threshold voltage of the core CMOS logic circuit Core is on or lower than the lower limit value L_lim(P) in FIG. 15 is cut in the step 94 in FIG. 9. Similarly, the fuse in the control memory Cnt_MM_p for nMOS of a chip in which the nMOS threshold voltage Vth(N) of the core CMOS logic circuit “Core” is on or lower than the lower limit value L_lim(N) in FIG. 15 is cut in the step 94 in FIG. 9. With respect to the chip in which the fuse in the control memory Cnt_MM_p for pMOS is cut, the absolute value |Vth(P)| of the average threshold voltage of all of pMOS in the core CMOS logic circuit “Core” is changed from low Vth to high Vth. Similarly, with respect to the chip in which the fuse in the control memory Cnt_MM_n for nMOS is cut, the average threshold voltage of all of nMOS in the core CMOS logic circuit “Core” is changed from low Vth to high Vth. As a result, a defective in the rhomboid defective part BF in FIG. 15 can be changed to the regenerated chip AF as a conforming item by using the two control memories Cnt_MM_p and Cnt_MM_n.

### <<Leakage Current Monitor Circuit>>

FIGS. 16A to 16E are circuit diagrams showing a semiconductor integrated circuit as further another embodiment of the invention. The MOS LSI chip “Chip” shown in FIGS. 16A to 16E basically differs from the MOS LSI chip “Chip” shown in FIG. 14 with respect to the point that, as shown in FIG. 16A, a pMOS monitor circuit Moni_pMOS for facilitating measurement of leakage current of the pMOS of the LSI and an nMOS monitor circuit Moni_NMOS for facilitating measurement of leakage current of the nMOS are added. As shown in FIG. 16B, the pMOS monitor circuit Moni_pMOS is constructed by a plurality of pMOS in which drain-source current paths are connected in parallel. By connecting the gates of the pMOS connected in parallel to the sources, the gate-source voltage is set to zero volt, and measurement of leakage current at Vgs of the pMOS=0 volt is facilitated. The sources and drains of the pMOS connected in parallel are led as external terminals T1_P and T2_P to the outside of the LSI chip. Similarly, as shown in FIG. 16C, the nMOS monitor circuit Moni_NMOS is constructed by a plurality of nMOS in which drain-source current paths are connected in parallel. By connecting the gates of the nMOS connected in parallel to the sources, the gate-source voltage is set to zero volt, and measurement of leakage current at Vgs of the nMOS=0 volt is facilitated. The drains and sources of the nMOS connected in parallel are led as external terminals T1_N and T2_N to the outside of the LSI chip. As the other pMOS monitor circuit Moni_pMOS and the other nMOS monitor circuit Moni_NMOS, as shown in FIGS. 16D and 16E, a plurality of pMOS gates and a plurality of nMOS gates can be led to the outside of the LSI chip as external terminals T3_P and T3_N. The other parts of the semiconductor integrated circuit of FIG. 16 are the same as those of the semiconductor integrated circuit shown in FIG. 14.

### <<Input Switch Circuit>>

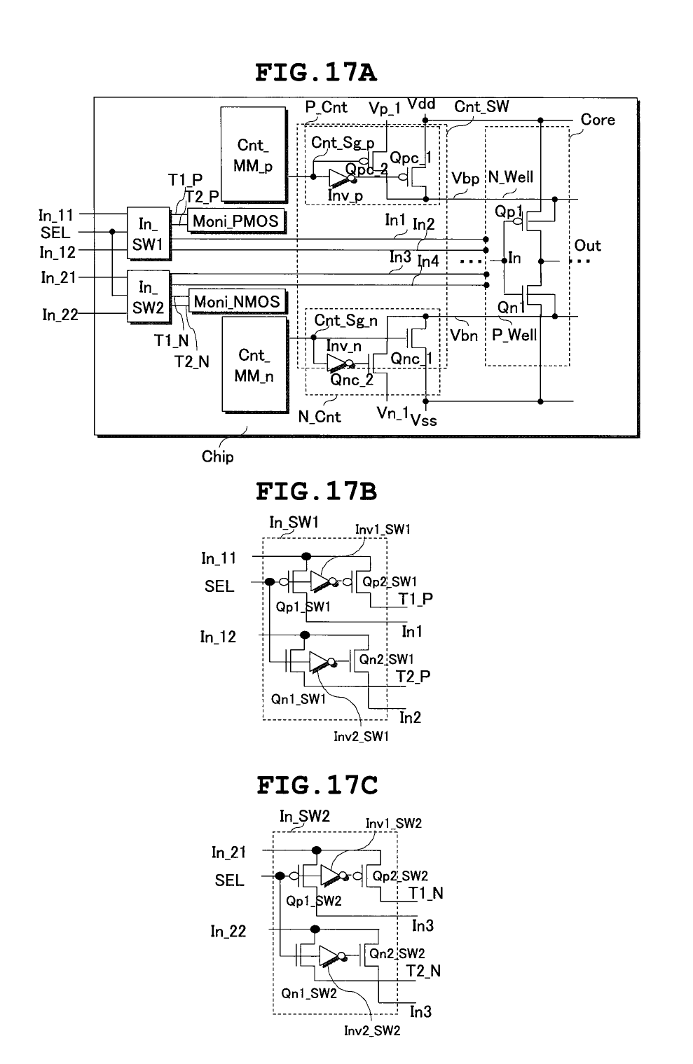

FIGS. 17A to 17C are circuit diagrams showing a semiconductor integrated circuit as further another embodiment of the invention. The MOS LSI chip “Chip” shown in FIGS. 17A to 17C basically differs from the MOS LSI chip “Chip” shown in FIGS. 16A to 16E with respect to the point that, as shown in FIG. 17A, input switch circuits In_SW1 and In_SW2 for switching between the input of the core CMOS logic circuit “Core” and inputs of the pMOS monitor circuit Moni_pMOS and the nMOS monitor circuit Moni_NMOS are added. Input terminals In_11, In_12, In_21, and In_22 of the input switch circuits In_SW1 and In_SW2 are used commonly as the input of the core CMOS logic circuit “Core” and the inputs of the pMOS monitor circuit Moni_pMOS and the nMOS monitor circuit Moni_NMOS. In the case where the input terminals In_11, In_12, In_21, and In_22 are used as inputs of the core CMOS logic circuit “Core”, a selection signal SEL is set to the low level. In the case where the input terminals are used as inputs of the pMOS monitor circuit Moni_pMOS and the nMOS monitor circuit Moni_NMOS, the selection signal SEL is set to the high level. In the input switch circuit In_SW1 of FIG. 17B, in the case where the selection signal SEL is at the low level, signals of the input terminals In_11 and In_12 of the input switch circuit In_SW1 are supplied to inputs In1 and In2 of the core CMOS logic circuit “Core” via the pMOS Qp1_SW1 and the nMOS Qn2_SW1 which are in the on state. In the case where the selection signal SEL is at the high level, signals of the input terminals In_11 and In_12 of the input switch circuit In_SW1 are supplied to inputs T1_P and T2_P of the pMOS monitor circuit Moni_pMOS via the pMOS Qp2_SW1 and the nMOS Qn1_SW1 which are in the on state. In the input switch circuit In_SW2 of FIG. 17C, in the case where the selection signal SEL is at the low level, signals of the input terminals In_21 and In_22 of the input switch circuit In_SW1 are supplied to inputs In3 and In4 of the core CMOS logic circuit “Core” via the pMOS Qp1_SW2 and the nMOS Qn2_SW2 which are in the on state. In the case where the selection signal SEL is at the high level, signals of the input terminals In_21 and In_22 of the input switch circuit In_SW1 are supplied to inputs T1_N and T2_N of the nMOS monitor circuit Moni_NMOS via the pMOS Qp2_SW2 and the nMOS Qn1_SW2 which are in the on state. The other parts of the semiconductor integrated circuit of FIGS. 17A to 17C are the same as those of the semiconductor integrated circuit shown in FIGS. 16A to 16E.

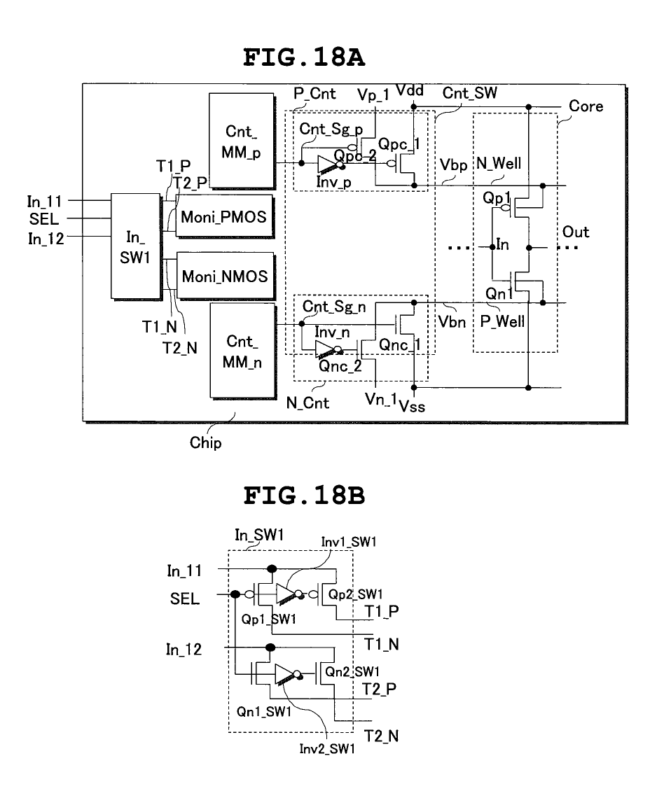

FIGS. 18A and 18B are circuit diagrams showing a semiconductor integrated circuit as further another embodiment of the invention. The MOS LSI chip “Chip” shown in FIGS. 18A and 18B basically differs from the MOS LSI chip “Chip” shown in FIGS. 16A to 16E with respect to the point that, as shown in FIG. 18A, the input switch circuit In_SW1 for switching between the input of the pMOS monitor circuit Moni_pMOS and the input of the nMOS monitor circuit Moni_NMOS is added. In the input switch circuit In_SW1 of FIG. 18B, in the case where the selection signal SEL is at the high level, signals of the input terminals In_11 and In_12 of the input switch circuit In_SW1 are supplied to the inputs T1_P and T2_P of the pMOS monitor circuit Moni_NMOS via the pMOS Qp2_SW1 and the nMOS Qn1_SW1 which are in the on state. In the case where the selection signal SEL is at the low level, signals of the input terminals In_11 and In_12 of the input switch circuit In_SW1 are supplied to inputs T1_N and T2_N of the nMOS monitor circuit Moni_NMOS via the pMOS Qp1_SW1 and the nMOS Qn2_SW1 which are in the on state. The other parts of the semiconductor integrated circuit of FIGS. 18A and 18B are the same as those of the semiconductor integrated circuit shown in FIGS. 16A to 16E.

### <<Test Control Signal>>

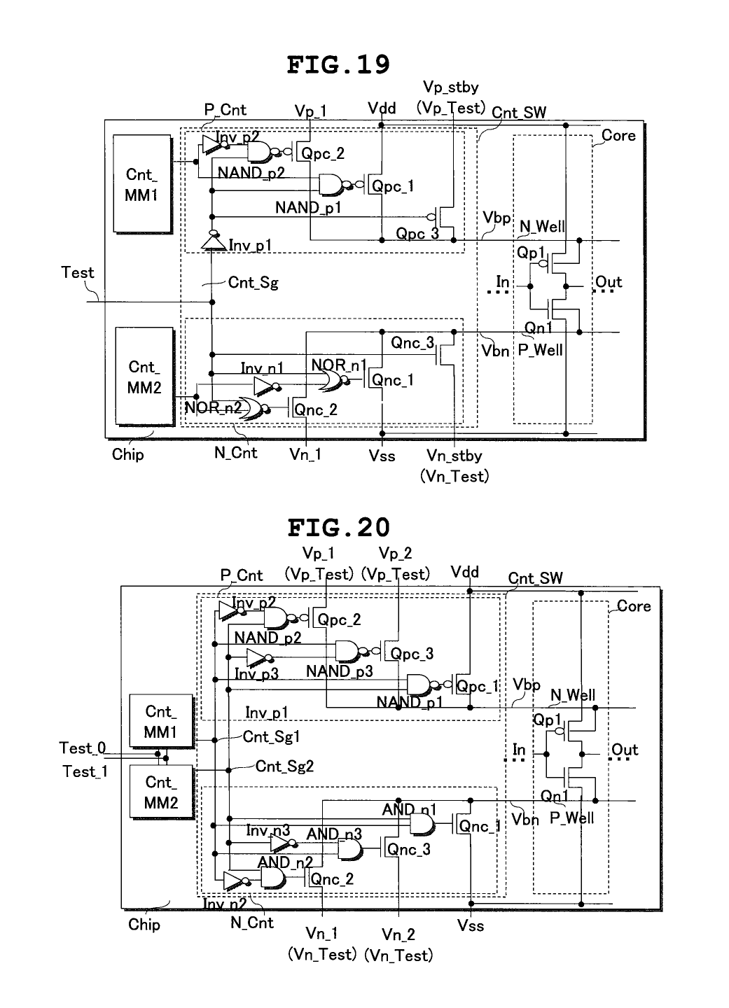

FIG. 19 is a circuit diagram showing a semiconductor integrated circuit as further another embodiment of the invention. A MOS LSI chip “Chip” shown in FIG. 19 basically differs from the MOS LSI chip “Chip” shown in FIG. 11 with respect to the point that the control memory is constructed by the control memories Cnt_MM1 and Cnt_MM2, and a test control signal “Test” is supplied. A test using the test control signal “Test” includes a test of determining whether the leakage current in the pMOS of the core CMOS logic circuit “Core” is large or not, and a test of determining whether the leakage current in the nMOS of the core CMOS logic circuit “Core” is large or not. In the test of the pMOS leakage current of the core CMOS logic circuit “Core”, for example, a high-level test input signal is supplied from a BIST (Built In Self-Test) circuit in the LSI is supplied to the input “In” of the core CMOS logic circuit “Core”. In this state, the leakage current of the pMOS Qp1 in the core CMOS logic circuit “Core” is measured by the external tester ATE as shown in FIG. 8. An N-well test voltage Vp_Test to be supplied to the N well of the pMOS Qp1 of the core CMOS logic circuit “Core” via the pMOS Qpc_3 of the NMOS controller which is turned on in response to a high-level test control signal “Test” is set to the level of the power source voltage Vdd. A P-well test voltage Vn_Test to be supplied to the P well of the nMOS Qp1 of the core CMOS logic circuit “Core” via the nMOS Qnc_3 of the nMOS controller which is turned on in response to the high-level test control signal “Test” is set to the low level which is almost the same as that of the P-well standby voltage Vn_stby. As a result, current of the nMOS Qn1 which is turned on in response to the high-level test input signal supplied to the input “In” of the core CMOS logic circuit “Core” can be largely reduced. The pMOS leakage current of the core CMOS logic circuit “Core” in this state can be measured from current flowing between the power source voltage Vdd and the ground voltage Vss by applying a voltage between the power source voltage Vdd and the ground voltage Vss. Next, in the test of the nMOS leakage current of the core CMOS logic circuit “Core”, for example, a low-level test input signal is supplied from the BIST circuit in the LSI to the input “In” of the core CMOS logic circuit “Core”. In this state, the leakage current of the nMOS Qn1 in the core CMOS logic circuit “Core” is measured by the external tester ATE as shown in FIG. 8. A P-well test voltage Vn_Test to be supplied to the P well of the nMOS Qn1 of the core CMOS logic circuit “Core” via the nMOS Qnc_3 of the nMOS controller which is turned on in response to a high-level test control signal “Test” is set to the level of the ground voltage Vss. An N-well test voltage Vp_Test to be supplied to the N well of the pMOS Qp1 of the core CMOS logic circuit “Core” via the pMOS Qpc_3 of the pMOS controller which is turned on in response to the high-level test control signal “Test” is set to the high level which is almost the same as that of the N-well standby voltage Vp_stby. As a result, current of the pMOS Qp1 which is turned on in response to the low-level test input signal supplied to the input “In” of the core CMOS logic circuit “Core” can be largely reduced. The nMOS leakage current of the core CMOS logic circuit “Core” in this state can be measured from current flowing between the power source voltage Vdd and the ground voltage Vss by applying a voltage between the power source voltage Vdd and the ground voltage Vss. The other parts of the semiconductor integrated circuit of FIG. 19 are the same as those of the semiconductor integrated circuit shown in FIG. 11.

FIG. 20 is a circuit diagram showing a semiconductor integrated circuit as further another embodiment of the invention. A MOS LSI chip “Chip” shown in FIG. 20 basically differs from the MOS LSI chip “Chip” shown in FIG. 13 with respect to the following point. In FIG. 20, the output signal Cnt_Sg1 of the control memory Cnt_MM1 becomes the 0 level in response to the high-level test control signal Test_0. The output signal Cnt_Sg2 of the control memory Cnt_MM2 becomes the 0 level in response to the high-level test control signal Test_1. In a test of the pMOS leakage current of the core CMOS logic circuit “Core”, for example, a high-level test input signal is supplied from the BIST circuit in the LSI to the input “In” of the core CMOS logic circuit “Core”. At this time, the test control signal Test_0 is set to the high level, so that the output signal Cnt_Sg1 of the control memory Cnt_MM1 becomes the “0” level. The test control signal Test_1 is set to the low level, so that the output signal Cnt_Sg2 of the control memory Cnt_MM2 becomes the “1” level. Therefore, the N-well first bias voltage Vp_1 supplied to the N well in the pMOS Qp1 in the core CMOS logic circuit “Core” via the pMOS Qpc2 in the on state in the pMOS controller P_Cnt is set to almost the level of the power source voltage Vdd. On the other hand, the P-well first bias voltage Vn_1 supplied to the P well in the nMOS Qn1 in the core CMOS logic circuit “Core” via the nMOS Qnc2 in the on state in the nMOS controller N_Cnt is set to almost the level of a P-well test bias voltage Vn_Test lower than the ground voltage Vss. As a result, current of the nMOS Qn1 which is turned on in response to the high-level test input signal supplied to the input “In” of the core CMOS logic circuit “Core” can be largely reduced. The leakage current of the pMOS in the core CMOS logic circuit “Core” can be measured from current flowing between the power source voltage Vdd and the ground voltage Vss by applying a voltage between the power source voltage Vdd and the ground voltage Vss. Next, in the test of the nMOS leakage current of the core CMOS logic circuit “Core”, for example, a low-level test input signal is supplied from the BIST circuit in the LSI to the input “In” of the core CMOS logic circuit “Core”. At this time, the test control signal Test_0 is set to the low level, so that the output signal Cnt_Sg1 of the control memory Cnt_MM1 becomes the “1” level. The test control signal Test_1 is set to the high level, so that the output signal Cnt_Sg2 of the control memory Cnt_MM2 becomes the “0” level. Therefore, the level of the P-well second bias voltage Vn_2 supplied to the P well in the nMOS Qn1 in the core CMOS logic circuit “Core” via the nMOS Qnc3 in the on state in the nMOS controller N_Cnt is set the ground voltage Vss. On the other hand, the level of the N-well second bias voltage Vp_2 supplied to the N well in the pMOS Qp1 in the core CMOS logic circuit “Core” via the pMOS Qpc3 in the on state in the pMOS controller P_Cnt is set to the level of an N-well test bias voltage Vp_Test higher than almost the power source voltage Vdd. As a result, current of the pMOS Qp1 which is turned on in response to the low-level test input signal supplied to the input “In” of the core CMOS logic circuit “Core” can be largely reduced. The leakage current of the nMOS in the core CMOS logic circuit “Core” in this state can be measured from current flowing between the power source voltage Vdd and the ground voltage Vss by applying a voltage between the power source voltage Vdd and the ground voltage Vss. The other parts of the semiconductor integrated circuit of FIG. 20 are the same as those of the semiconductor integrated circuit shown in FIG. 13.

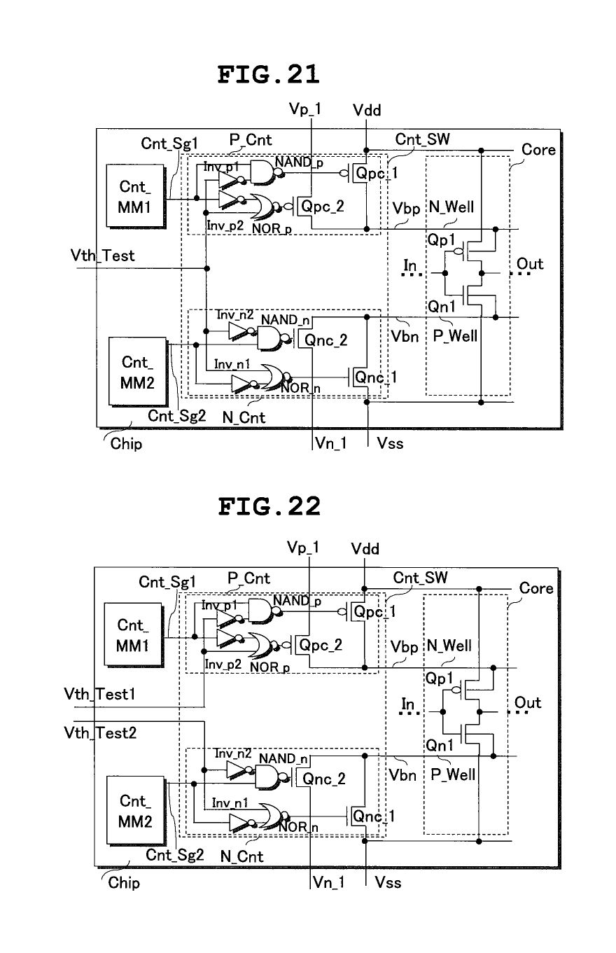

FIG. 21 is a circuit diagram showing a semiconductor integrated circuit as further another embodiment of the invention. A MOS LSI chip “Chip” shown in FIG. 21 basically differs from the MOS LSI chip “Chip” shown in FIG. 14 with respect to the following point. In FIG. 21, the configuration of the pMOS controller P_Cnt and the nMOS controller N_Cnt is changed, and the test control signal Vth_Test is applied to the pMOS controller P_Cnt and the nMOS controller N_Cnt. The pMOS controller P_Cnt includes the inverters Inv_p1 and Inv_p2, a NAND circuit NAND_p, and a NOR circuit NOR_p. The nMOS controller N_Cnt includes the inverters Inv_n1 and Inv_n2, a NAND circuit NAND_n, and a NOR circuit NOR_n. At the time of measuring pMOS leakage current and nMOS leakage current in the core CMOS logic circuit “Core”, the high-level test control signal Vth_Test is supplied to the pMOS controller P_Cnt and the nMOS controller N_Cnt.

In a test of the pMOS leakage current of the core CMOS logic circuit “Core”, for example, a high-level test input signal is supplied from the BIST circuit in the LSI to the input “In” of the core CMOS logic circuit “Core” Therefore, the level of the N-well first bias voltage Vp_1 supplied to the N well in the pMOS Qp1 in the core CMOS logic circuit “Core” via the pMOS Qpc2 in the on state in the pMOS controller P_Cnt is set to almost the power source voltage Vdd. The level of the P-well first bias voltage Vn_1 supplied to the P well in the nMOS Qn1 in the core CMOS logic circuit “Core” via the nMOS Qnc2 in the on state in the nMOS controller N_Cnt is set to a level lower than the ground voltage Vss. As a result, current of the nMOS Qn1 which is turned on in response to the high-level test input signal supplied to the input “In” of the core CMOS logic circuit “Core” can be largely reduced. The leakage current of the pMOS in the core CMOS logic circuit “Core” can be measured from current flowing between the power source voltage Vdd and the ground voltage Vss by applying a voltage between the power source voltage Vdd and the ground voltage Vss. Next, in the test of the nMOS leakage current of the core CMOS logic circuit “Core”, for example, a low-level test input signal is supplied from the BIST circuit in the LSI to the input “In” of the core CMOS logic circuit “Core”. Therefore, the level of the P-well first bias voltage Vn_1 supplied to the P well in the nMOS Qn1 in the core CMOS logic circuit “Core” via the nMOS Qnc2 in the on state in the nMOS controller N_Cnt is set almost the ground voltage Vss. The level of the N-well first bias voltage Vp_1 supplied to the N well in the pMOS Qp1 in the core CMOS logic circuit “Core” via the pMOS Qpc2 in the on state in the pMOS controller P_Cnt is set to a level higher than the power source voltage Vdd. As a result, current of the pMOS Qp1 which is turned on in response to the low-level test input signal supplied to the input “In” of the core CMOS logic circuit “Core” can be largely reduced. The leakage current of the nMOS in the core CMOS logic circuit “Core” in this state can be measured from current flowing between the power source voltage Vdd and the ground voltage Vss by applying a voltage between the power source voltage Vdd and the ground voltage Vss. The other parts of the semiconductor integrated circuit of FIG. 21 are the same as those of the semiconductor integrated circuit shown in FIG. 14.

FIG. 22 is a circuit diagram showing a semiconductor integrated circuit as further another embodiment of the invention. A MOS LSI chip “Chip” shown in FIG. 22 basically differs from the MOS LSI chip “Chip” shown in FIG. 21 with respect to the following point. In FIG. 22, a test control signal Vth_Test1 is supplied to the pMOS controller P_Cnt, and a test control signal Vth_Test2 is supplied to the nMOS controller N_Cnt.

In a test of the pMOS leakage current of the core CMOS logic circuit “Core”, for example, a high-level test input signal is supplied from the BIST circuit in the LSI to the input “In” of the core CMOS logic circuit “Core” At this time, the high-level test control signal Vth_Test1 is supplied to the pMOS controller P_Cnt, and the high-level test control signal Vth_Test2 is supplied to the nMOS controller N_Cnt. Therefore, the level of the N-well first bias voltage Vp_1 supplied to the N well in the pMOS Qp1 in the core CMOS logic circuit “Core” via the pMOS Qpc2 in the on state in the pMOS controller P_Cnt is set to almost the power source voltage Vdd. The level of the P-well first bias voltage Vn_1 supplied to the P well in the nMOS Qn1 in the core CMOS logic circuit “Core” via the nMOS Qnc2 in the on state in the nMOS controller N_Cnt is set to a level lower than the ground voltage Vss. As a result, current of the nMOS Qn1 which is turned on in response to the high-level test input signal supplied to the input “In” of the core CMOS logic circuit “Core” can be largely reduced. The leakage current of the pMOS in the core CMOS logic circuit “Core” can be measured from current flowing between the power source voltage Vdd and the ground voltage Vss by applying a voltage between the power source voltage Vdd and the ground voltage Vss. Next, in the test of the nMOS leakage current of the core CMOS logic circuit “Core”, for example, a low-level test input signal is supplied from the BIST circuit in the LSI to the input “In” of the core CMOS logic circuit “Core”. At this time as well, the high-level test control signal Vth_Test1 is supplied to the pMOS controller P_Cnt, and the high-level test control signal Vth_Test2 is supplied to the nMOS controller N_Cnt. Therefore, the level of the P-well first bias voltage Vn_1 supplied to the P well in the nMOS Qn1 in the core CMOS logic circuit “Core” via the nMOS Qnc2 in the on state in the nMOS controller N_Cnt is set almost the ground voltage Vss. The level of the N-well first bias voltage Vp_1 supplied to the N well in the pMOS Qp1 in the core CMOS logic circuit “Core” via the pMOS Qpc2 in the on state in the pMOS controller P_Cnt is set to a level higher than the power source voltage Vdd. As a result, current of the pMOS Qp1 which is turned on in response to the low-level test input signal supplied to the input “In” of the core CMOS logic circuit “Core” can be largely reduced. The leakage current of the nMOS in the core CMOS logic circuit “Core” in this state can be measured from current flowing between the power source voltage Vdd and the ground voltage Vss by applying a voltage between the power source voltage Vdd and the ground voltage Vss. The other parts of the semiconductor integrated circuit of FIG. 22 are the same as those of the semiconductor integrated circuit shown in FIG. 21.

### <<Wafer Test and Wafer Process>>

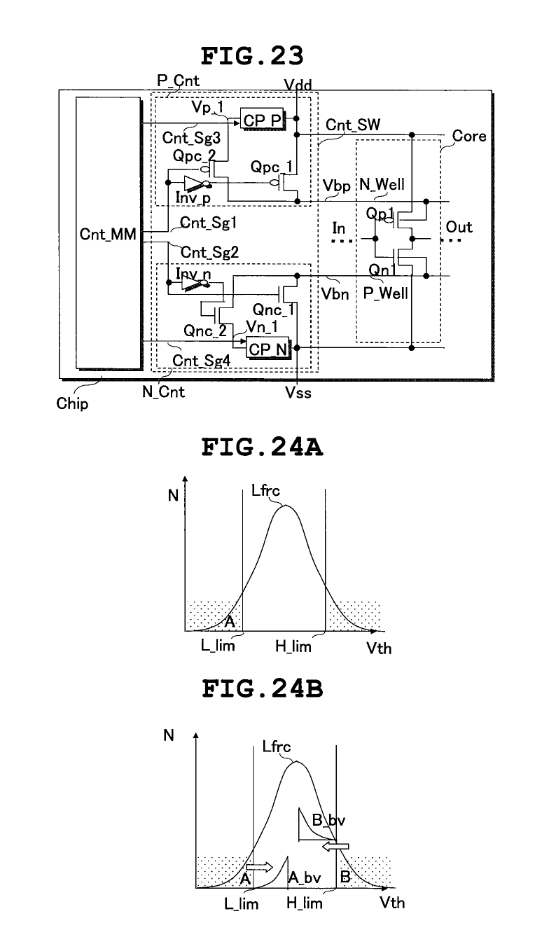

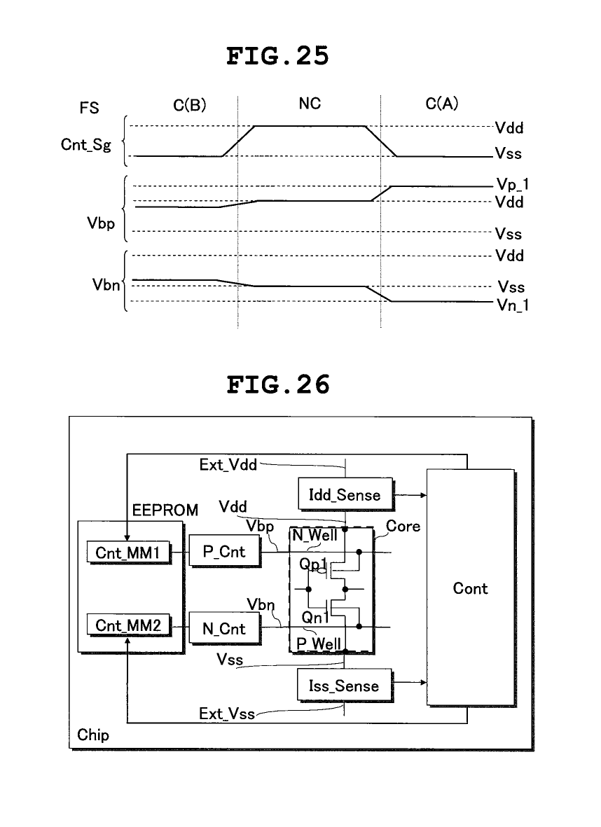

FIG. 23 is a circuit diagram showing a semiconductor integrated circuit as further another embodiment of the invention. A MOS LSI chip “Chip” shown in FIG. 23 basically differs from the MOS LSI chip “Chip” shown in FIG. 1 with respect to the following point. In FIG. 23, in a manner similar to FIG. 1, not only a fuse in a chip group A in which the threshold voltage Vth of the MOS LSI drops to the lower limit threshold L_Lim or less as shown in FIG. 24A but also a fuse in a chip group B in which the threshold voltage Vth rises to the upper limit threshold H_Lim or higher as shown in FIG. 24B are cut. However, the chip group B in which the threshold voltage Vth of the MOS LSI increases to the upper limit threshold value H_Lim or higher is controlled as follows. First, the N-well bias voltage Vp_1 applied from the voltage generator CP_P in the pMOS controller Cnt_P to the N well in the pMOS Qp1 in the core CMOS logic circuit “Core” via the pMOS Qpc_2 is changed to a level slightly lower than the power source voltage Vdd. The P-well bias voltage Vn_1 applied from the voltage generator CP_N in the nMOS controller Cnt_N to the P well in the nMOS Qn1 in the core CMOS logic circuit “Core” via the nMOS Qnc_2 is changed to a level slightly higher than the ground voltage Vss. The relations of voltages in the parts in the semiconductor integrated circuit shown in FIG. 23 are shown in a cut state C(B) at the left part of FIG. 25. FIG. 25 is a diagram showing the relations of voltages of the parts in the semiconductor integrated circuit illustrated in FIG. 23. As shown in the cut state C(B) at the left part of FIG. 25, the N-well bias voltage Vp_1 of the pMOS Qp1 is set slightly lower than the power source voltage Vdd of the source, and the P-well bias voltage Vn_1 of the nMOS Qn1 is set to be slightly higher than the ground voltage Vss of the source. As a result, the threshold voltage of the pMOS Qp1 and the nMOS Qn1 in the core CMOS logic circuit “Core” is decreased from very high Vth, and delay time of the core CMOS logic circuit “Core” changes from an excessive state to a proper state. FIGS. 24A and 24B are diagrams each showing a distribution of the threshold voltage Vth of the semiconductor integrated circuit illustrated in FIG. 23. Therefore, the chip group B existing at the upper limit threshold H_Lim in FIG. 24 or higher is changed to a regeneration chip group B_bv by the above-described control. As a result, the average threshold voltage Vth of all of pMOS and all of nMOS of the core CMOS logic circuit “Core” in the MOS LSI chip drops to the upper limit threshold H_Lim or below, and the delay time of the whole chip can be reduced.

### <<Measurement of Leakage Current on Chip and Compensation of Change with Time>>

FIG. 26 is a circuit diagram showing a semiconductor integrated circuit as further another embodiment of the invention. On the MOS LSI chip “Chip” shown in FIG. 26, the pMOS leakage current and the nMOS leakage current in the core CMOS logic circuit “Core” can be measured. In the MOS LSI chip “Chip” shown in FIG. 26, the pMOS and nMOS leakage currents in the core CMOS logic circuit “Core” are measured as shown in FIGS. 8 and 9 at the stage of wafer manufacture. According to the result of measurement of the leakage current at the wafer manufacture stage, a nonvolatile program is executed in the control memories Cnt_MM1 and Cnt_MM2 in an EEPROM as a nonvolatile memory device. As a result, variations in the threshold voltages of pMOS and nMOS in the core CMOS logic circuit “Core” at the wafer manufacture stage can be compensated as described above.

However, the value of the pMOS and nMOS threshold voltages in the core CMOS logic circuit “Core” fluctuates with time due to severe stress of long time on the LSI. On the MOS LSI chip “Chip” shown in FIG. 26, a control unit “Cont” periodically measures the pMOS and nMOS leakage currents in the core CMOS logic circuit “Core” in accordance with a maintenance program stored in the EEPROM as a nonvolatile memory device. The pMOS leakage current is measured by a first sense circuit Idd_Sense connected between the external power source Ext_Vdd and the source of the pMOS, and the nMOS leakage current can be measured by a second sense circuit Iss_Sense connected between the external ground Ext_Vss and the source of the nMOS. In the case where the measured pMOS and nMOS leakage currents change by a predetermined allowable range or more from a past value, the control unit “Cont” programs new compensation data in a nonvolatile manner in the control memories Cnt_MM1 and Cnt_MM2 in the EEPROM as a nonvolatile memory device. As a result, fluctuations in the pMOS and NMOS threshold voltages in the core CMOS logic circuit “Core” caused by change with time due to severe stress for long time of the LSI can be compensated.

### <<Built-In SRAM>>

FIG. 27 is a circuit diagram showing a built-in SRAM formed on the chip of a semiconductor integrated circuit together with the core CMOS logic circuit “Core” described with reference to FIGS. 1 to 26. In FIG. 27, a built-in SRAM (static random access memory) in a chip “Chip” of a semiconductor integrated circuit includes a plurality of cells Cell00 . . . Cellnm disposed in a matrix in “n” rows and “m” columns. Each of the cells is a CMOS SRAM cell of one bit. The semiconductor integrated circuit chip “Chip” includes the control memories Cnt_MM1 and Cnt_MM2 and the control switch Cnt_SW for compensating characteristic variations of the SRAM. The control switch Cnt_SW includes the pMOS controller P_Cnt and the nMOS controller N_Cnt.

### <<Configuration of SRAM Cell>>

For example, the SRAM memory cell Cell00 of one bit includes pMOS Qp1 and Qp2 whose sources are connected to the power source voltage Vdd, nMOS Qn1 and Qn2 whose sources are connected to the ground voltage Vss, and nMOS Qn3 and Qn4 whose gates are connected to a word line WL0. The pMOS Qp1 and Qp2 operate as a pair of load transistors, the nMOS Qn1 and Qn2 operate as a pair of drive transistors, and NMOS Qn3 and Qn4 operate as a pair of transfer transistors. The drain of the load pMOS Qp1 and the drain of the drive nMOS Qn1 are connected to one storage node N1. The drain of the load pMOS Qp2 and the drain of the drive nMOS Qn2 are connected to the other storage node N2. The gate of the load pMOS Qp1 and the gate of the drive nMOS Qn1 are connected to the other storage node N2. The gate of the load pMOS Qp2 and the gate of the drive nMOS Qn2 are connected to the storage node N1. As a result, in an information holding mode in which the word line WL0 is at the low level as a non-selection level and the pair of transfer MOS transistors Qn3 and Qn4 are off, information in the pair of storage nodes N1 and N2 can be held.

In an information writing mode, the word line WL0 is driven to a high level, and the pair of transfer MOS transistors Qn3 and Qn4 are turned on. Information of the pair of data linesDL0 and /DL0 is written in the pair of storage nodes N1 and N2 via the pair of transfer MOS transistors Qn3 and Qn4.

In an information reading mode, the word line WL0 is driven to a high level, and the pair of transfer MOS transistors Qn3 and Qn4 are turned on. A pair of data pieces stored in the pair of storage nodes N1 and N2 can be read to the pair of data lines DL0 and /DL0 via the pair of transfer MOS transistors Qn3 and Qn4.

### <<Operation Limit of SRAM Cell>>

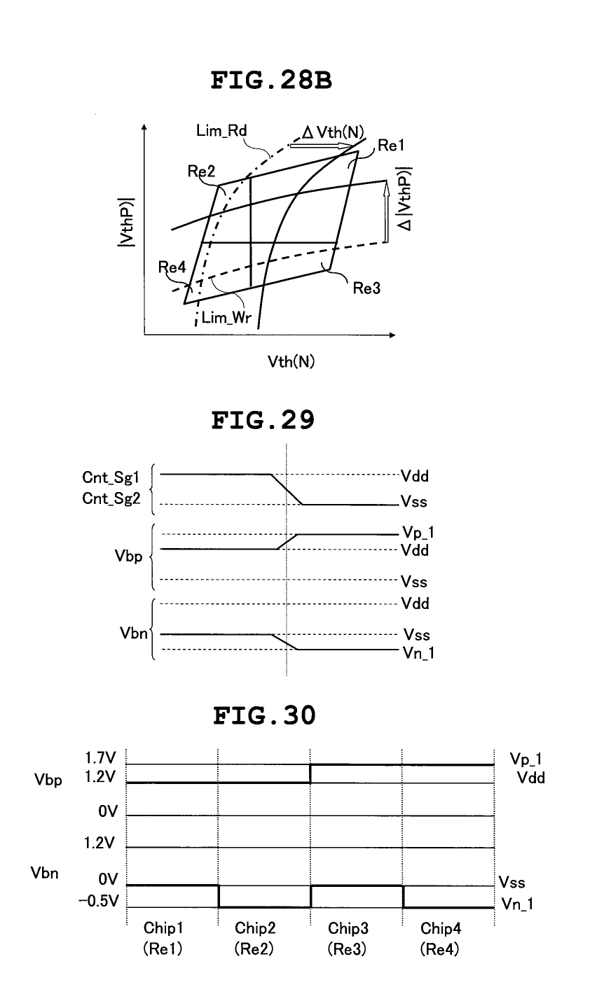

FIG. 28A is a diagram showing an electric characteristic of an SRAM cell depending on variations in the nMOS threshold voltage Vth(N) and the absolute value |Vth(P)| of the pMOS threshold voltage in the SRAM cell. The horizontal axis of the diagram indicates the nMOS threshold voltage Vth(N), and the vertical axis of the diagram shows the absolute value |Vth(P)| of the pMOS threshold voltage. In the diagram, a limit line Lim_Rd of reading operation and a limit line Lim_Wr of writing operation of the SRAM cell are also shown. Further, in the diagram, a rhomboid made by regions Re1, Re2, Re3, and Re4 indicates a distribution of variations in the nMOS threshold voltage Vth(N) and the absolute value |Vth(P)| of the pMOS threshold voltage in the SRAM cell.

### <<Limit of Reading Operation>>

When the distribution of the threshold voltage of the SRAM cell is positioned below the limit line Lim_Rd of the reading operation in FIG. 28A, information can be read normally from the SRAM cell. When the distribution of the threshold voltage of the SRAM cell is positioned above the limit line Lim_Rd of the reading operation in FIG. 28A, information cannot be read normally from the SRAM cell. When the distribution of the threshold voltage of the SRAM cell is positioned above the limit line Lim_Rd of the reading operation in FIG. 28A, the nMOS threshold voltage Vth (N) is too low as shown by the regions Re2 and Re4. In the region Re4, the absolute value |Vth(P)| of the pMOS threshold voltage is also too low. In the region Re2, the absolute value |Vth(P)| of the pMOS threshold voltage is proper. When the nMOS threshold voltage Vth(N) is too low as in the regions Re2 and Re4, low-level information stored in one of the pair of storage nodes N1 and N2 is destroyed in the reading operation of the SRAM cell. It is caused when the current in the pair of transfer MOS transistors Qn3 and Qn4 becomes excessive due to decrease in the NMOS threshold voltage Vth(N). That is, since current from the bias voltage (normally, voltage which is the half of the power source voltage Vdd) of a sense amplifier for reading flows in the low-level storage node via the transfer MOS transistor in the reading operation of the SRAM cell, destruction of the low-level stored information occurs. Therefore, an MOS LSI chip positioned on the limit line Lim_Rd of the reading operation in the regions Re2 and Re4 in FIG. 28A is discarded as a defective before achievement of the present invention.

### <<Limit of Writing Operation>>

When the distribution of the threshold voltage of the SRAM cell is positioned on the limit line Lim_Wr of the writing operation in FIG. 28A, normal writing from the SRAM cell becomes possible. When the distribution of the threshold voltage of the SRAM cell is positioned below the limit line Lim_Wr of the writing operation in FIG. 28A, normal writing from the SRAM cell becomes impossible. When the distribution of the threshold voltage of the SRAM cell is positioned below the limit line Lim_Wr of the writing operation in FIG. 28A, the absolute value |Vth(P)| of the pMOS threshold voltage is too low like in the regions Re3 and Re4. In the region Re4, the nMOS threshold voltage Vth(N) is also too low in the region Re4, and the nMOS threshold voltage Vth(N) is proper in the region Re3. When the absolute value |Vth(P)| of the pMOS threshold voltage is too low like in the regions Re3 and Re4, low-level information cannot be written to the storage node in the writing operation of the SRAM cell. It is caused when the current in the pair of load pMOS transistors Qp1 and Qp2 becomes excessive due to decrease in the absolute value |Vth(P)| of the pMOS threshold voltage. That is, at the time of writing of the SRAM cell, information of the pair of data lines DL0 and /DL0 is transmitted to the pair of storage nodes N1 and N2 via the pair of transfer MOS transistors Qn3 and Qn4. In particular, since low-level information is transmitted, new information can be written in the SRAM cell. However, the current in the pair of load pMOS transistors Qp1 and Qp2 becomes excessive and, consequently, the low-level information is not transmitted. Therefore, a MOS LSI chip positioned below the limit line Lim_Wr of the writing operation in the regions Re3 and Re4 in FIG. 28A is discarded as a defective before achievement of the present invention.

### <<Control Memory and Control Switch for Built-In SRAM>>

In the semiconductor integrated circuit chip “Chip” shown in FIG. 27, the control memories Cnt_MM1 and Cnt_MM2 and the control switch Cnt_SW for compensating characteristic variations in the SRAM execute an extremely important compensating function.

In the semiconductor integrated circuit chip “Chip” shown in FIG. 27, before compensating characteristic variations in the SRAM, a chip to be compensated is selected from a wafer. The chips to be compensated are a chip using the low threshold voltage Vth (N) positioned on the limit line Lim_Rd of the reading operation in the regions Re2 and Re4 in FIG. 28A and a chip using the low threshold voltage |Vth(P)| positioned below the limit line Lim_Wr of the writing operation in the regions Re3 and Re4 in FIG. 28A.

### <<Programming to Control Memory for Built-In SRAM>>

nMOS low-threshold-voltage information is programmed in a nonvolatile manner in the control memory Cnt_MM2 of the chip using the low threshold voltage Vth(N) selected from the wafer. pMOS low-threshold-voltage information is programmed in a nonvolatile manner in the control memory Cnt_MM1 of the chip using the low threshold voltage |Vth(P)| selected from the wafer. On start of operation of the MOS LSI chip “Chip” in which the low-threshold-voltage information is programmed, the output signals Cnt_Sg1 and Cnt_Sg2 of the control memories Cnt_MM1 and Cnt_MM2 are, for example, low-level ground voltage Vss(GND).

### <<Configuration of Control Switch for Built-In SRAM>>

The pMOS controller P_Cnt is constructed by the pMOS Qpc_1, the pMOS Qpc_2, and the inverter Inv_p. In the pMOS controller P_Cnt, the power source voltage Vdd is applied to the source of the pMOS Qpc_1, and the N-well bias voltage Vp_1 higher than the power source voltage Vdd is applied to the source of the pMOS Qpc_2. The drain of the pMOS Qpc_1 and the drain of the pMOS Qpc_2 are connected to the N wells N_Well in the load pMOS Qp1 and Qp2 in the SRAM cell.

The nMOS controller N_Cnt is constructed by the nMOS Qnc_1, the nMOS Qnc_2, and the inverter Inv_n. In the nMOS controller N_Cnt, the ground voltage Vss is applied to the source of the nMOS Qnc_1, and the P-well bias voltage Vn_1 lower than the ground voltage Vss is applied to the source of the nMOS Qnc_2. The drain of the nMOS Qnc_1 and the drain of the nMOS Qnc_2 are connected to the P wells P_Well in the driver nMOS Qn1 and Qn2, and the transfer nMOS Qn3 and Qn4 in the SRAM cell.

### <<Control on Body Bias Voltage by Control Switch for Built-In SRAM>>

When the output signals Cnt_Sg1 and Cnt_Sg2 of the control memories Cnt_MM1 and Cnt_MM2 become the high level, the pMOS Qpc_1 in the pMOS controller P_Cnt is turned on, and the nMOS Qnc_1 of the nMOS controller N_Cnt is turned on. The power source voltage Vdd is applied as the pMOS body bias voltage Vbp to the N wells N_Well in the load pMOS Qp1 and Qp2 in the SRAM memory cell, and the ground voltage Vss is applied as the nMOS body bias voltage Vbn to the P wells P_Well in the driver nMOS Qn1 and Qn2 and the transfer nMOS Qn3 and Qn4 in the SRAM memory cell. On the other hand, the power source voltage Vdd is supplied to the sources of the load pMOS Qp1 and Qp2 in the SRAM cell, and the ground voltage Vss is supplied to the sources of the driver nMOS Qn1 and Qn2. Therefore, the power source voltage Vdd is commonly applied to the sources of the load pMOS Qp1 and Qp2 and the N well N_Well in the SRAM cell, and the ground voltage Vss is commonly applied to the sources of the driver nMOS Qn1 and Qn2 and the P well P_Well in the SRAM cell.

When the output signal Cnt_Sg1 of the control memory Cnt_MM1 changes from the high level to the low level, the pMOS Qpc_2 in the pMOS controller P_Cnt is turned on. The N-well bias voltage Vp_1 higher than the power source voltage Vdd is applied as the body bias voltage Vbp to the N wells N_Well in the load pMOS Qp1 and Qp2 in the SRAM cell. Since the power source voltage Vdd is applied to the sources of the load pMOS Qp1 and Qp2 in the SRAM cell, the N-well bias voltage Vp_1 applied to the N-well N_Well becomes the reverse body bias of the power source voltage Vdd applied to the sources of the load pMOS Qp1 and Qp2 in the SRAM cell. As a result, the load pMOS Qp1 and Qp2 in the SRAM cell can be controlled from the low threshold voltage to the high threshold voltage |Vth(P)|.

When the output signal Cnt_Sg2 of the control memory Cnt_MM2 changes from the high level to the low level, the nMOS Qnc_2 in the nMOS controller N_Cnt is turned on. The P-well bias voltage Vn_1 lower than the ground voltage Vss is applied as the nMOS body bias voltage Vbn to the P wells P_Well in the driver nMOS Qn1 and Qn2 and the transfer nMOS Qn3 and Qn4. Since the ground voltage Vss is applied to the sources of the driver nMOS Qn1 and Qn2 in the SRAM cell, the P-well bias voltage Vn_1 applied to the P-well P_Well becomes the reverse body bias of the ground voltage Vss applied to the sources of the driver nMOS Qn1 and Qn2 in the SRAM cell. As a result, the driver nMOS Qn1 and Qn2 and the transfer nMOS Qn3 and Qn4 in the SRAM cell can be controlled from the low threshold voltage to the high threshold voltage Vth(N).

FIG. 29 is a diagram showing changes in the pMOS body bias voltage Vbp of the load pMOS Qp1 and Qp2 in the SRAM cell and the nMOS body bias voltage Vbn of the driver nMOs Qn1 and Qn2 and the transfer nMOS Qn3 and Qn4 in the SRAM cell due to level changes in the output signals Cnt_Sg1 and Cnt_Sg2 of the control memories Cnt_MM1 and Cnt_MM2. By the change from the left to the right in FIG. 29, the load pMOS Qp1 and Qp2 of the SRAM cell is controlled from the low threshold voltage to the high threshold voltage |Vth(P)|, and the driver nMOS Qn1 and Qn2 and the transfer nMOS Qn3 and Qn4 in the SRAM cell can be controlled from the low threshold voltage to the high threshold voltage Vth(N).

FIG. 30 is a diagram showing the body bias voltages Vbp and Vbn applied to the chips Chip2, Chip3, and Chip4 corresponding to the regions Re2, Re3, and Re4 close to the limit line Lim_Rd of the reading operation and the limit line Lim_Wr of the writing operation in FIG. 28A due to the level changes in the output signals Cnt_Sg1 and Cnt_Sg2 of the control memories Cnt_MM1 and Cnt_MM2. In the chip Chip1 corresponding to the region Re1 which is not close to the limit line Lim_Rd of the reading operation and the limit line Lim_Wr of the writing operation, the nMOS threshold voltage Vth(N) and the absolute value |Vth(P)| of the pMOS threshold voltage are proper values. Therefore, in the chip Chip1 corresponding to the region Re1, the pMOS body bias voltage Vbp is set to the power source voltage Vdd, and the nMOS body bias voltage Vbn is set to the ground voltage Vss. In the chips Chip2 and Chip4 corresponding to the regions Re2 and Re4 close to the limit line Lim_Rd of the reading operation in FIG. 28A, the nMOS threshold voltage Vth(N) is low. In the chips Chip2 and Chip4, the output signal Cnt_Sg2 of the control memory Cnt_MM2 becomes the low level. Therefore, the driver nMOS Qn1 and Qn2 and the transfer nMOS Qn3 and Qn4 in the SRAM cell to which the nMOS body bias voltage Vbn lower than the ground voltage Vss (by −0.5V) is applied can be controlled from the low threshold voltage to the high threshold voltage Vth(N). In the chips Chip3 and Chip4 corresponding to the regions Re3 and Re4 close to the limit line Lim_Wr of the writing operation in FIG. 28A, the absolute value |Vth(P)| of the pMOS threshold voltage is low. In the chips Chip3 and Chip4, the output signal Cnt_Sg1 of the control memory Cnt_MM1 becomes the low level. Therefore, the load pMOS Qp1 and Qp2 in the SRAM cell to which the pMOS body bias voltage Vbp higher than the power source voltage Vdd (by 1.2V) is applied can be controlled from the low threshold voltage to the high threshold voltage |Vth(P)|.

FIG. 28B is a diagram showing a state where an effective threshold voltage in the operation of the chip is controlled to a proper value by application of the body bias voltage to the chip using the control memories Cnt_MM1 and Cnt_MM2 and the control switch Cnt_SW described by referring to FIG. 30 and, as a result, the manufacture yield of the MOS LSI improves. As shown in FIG. 28B, in the chips Chip2 and Chip4 corresponding to the regions Re2 and Re4 close to the limit line Lim_Rd of the reading operation in FIG. 28A, the NMOS threshold voltage Vth(N) after start of the operation effectively increases by ΔVth(N). Therefore, all of SRAM cells in the chips Chip2 and Chip4 can perform normal reading operation. In the chips Chip3 and Chip4 corresponding to the regions Re3 and Re4 close to the limit line Lim_Wr of the writing operation in FIG. 28A, the absolute value |Vth(P)| of the pMOS threshold voltage after start of the operation effectively increases by Δ|Vth(P)|. Therefore, all of SRAM cells in the chips Chip3 and Chip4 can perform normal writing operation.

Although the present invention achieved by the inventors herein has been concretely described on the basis of thee embodiments, obviously, the invention is not limited to the embodiments but can be variously changed without departing from the gist of the invention.

For example, the present invention can be also applied to a system LSI.

### <<System LSI>>

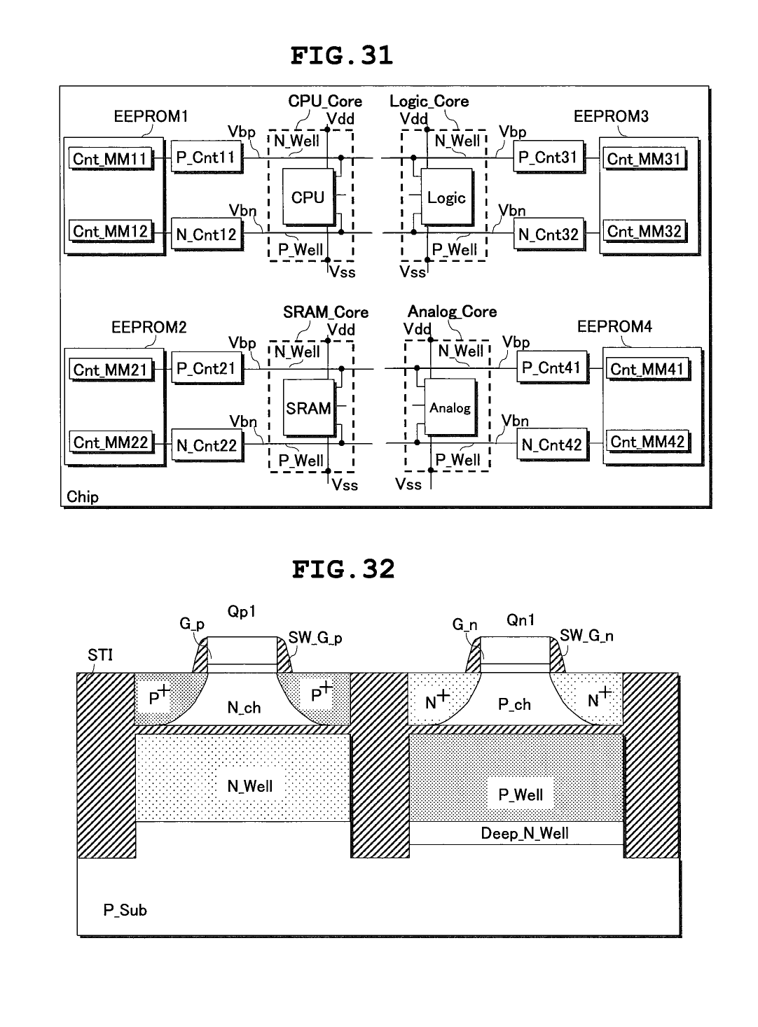

FIG. 31 is a diagram showing a system LSI including, in a chip, a CPU core CPU_Core, a logic core Logic_Core, an SRAM core SRAM_Core, and an analog core Analog_Core. Each of the four cores is constructed by a CMOS.

In the upper left CPU core CPU_Core and the upper right logic core Logic_Core, like the core CMOS logic core “Core” described with reference to FIGS. 1 to 26, variations in the threshold voltages of the MOS transistors can be compensated with small overhead.

In the lower left SRAM core SRAM_Core, like the SRAM core described with reference to FIGS. 27 to 30, a built-in SRAM can be manufactured at high manufacture yield. Variations in the threshold voltages in the driver nMOS, the load pMOS, and the transfer nMOS causing an error in the reading and writing operations of the built-in SRAM can be also compensated.

The lower right analog core Analog_Core includes, for example, a CMOS amplifier and a CMOS oscillator. By control information stored in the control memories Cnt_MM1 and Cnt_MM2 of an EEPROM 4 as a nonvolatile memory, the pMOS body bias voltage and the nMOS body bias voltage of the analog core Analog_Core can be adjusted. Therefore, variations in the pMOS and nMOS threshold voltages of the CMOS amplifier and the CMOS oscillator in the analog core Analog_Core can be compensated, so that the electric characteristics of the CMOS amplifier and the CMOS oscillator can be set with high precision. The lower right analog core Analog_Core can include an A/D converter for converting an analog signal to a digital signal and a D/A converter for converting a digital signal to an analog signal. Since variations in the pMOS and nMOS threshold voltages of the converters can be compensated, the precision of the A/D conversion and the D/A conversion can be improved.

### <<SOI Device>>

FIG. 32 is a diagram showing a sectional structure of a semiconductor integrated circuit as further another embodiment of the invention. A MOS LSI shown in FIG. 32 employs an SOI (Silicon-On-Insulator) structure.

As shown in FIG. 32, the SOI structure has, for example, a P-type silicon substrate P_Sub as a lower layer. On the surface of the silicon substrate P_Sub as the lower layer, an N well N_Well and a P well P_Well are formed. Between the N well N_Well and the P well P_Well, an STI (Shallow Trench Isolation) layer as an insulator device isolation area is formed.

Over the silicon substrate P_Sub on which the N well N_Well and the P well P_Well are formed, a thin insulator is formed.

On the thin insulator, a silicon layer is formed. On the left side of the silicon layer, a P-type source area and a P-type drain area of high impurity concentration and an N-type channel area controlled to have a very low dose of the pMOS Qp1 are formed. On the right side of the silicon layer, an N-type source area and an N-type drain area of high impurity concentration and a P-type channel area controlled to have a very low dose amount of an nMOS Qn1 are formed.

Since an oxide film as the thin insulator is buried in the silicon layer, the thin insulator is called a buried oxide (BOX). The N-type channel area controlled to have a very low dose of the pMOS Qp1 is fully depleted, and the P-type channel area controlled to have a very low dose in the nMOS Qn1 is also fully depleted. Therefore, the pMOS Qp1 and the nMOS Qn1 are fully-depleted (FD) SOI transistors. The threshold voltages of the pMOS Qp1 and the nMOS Qn1 of the fully-depleted SOI transistors can be controlled by the body bias voltages of the N well N_Well and the P well P_Well just below the thin insulator called a back gate. In such a BOX FD-SOI transistor, the junction capacitance between the drain and the well can be largely reduced. Thus, it is suitable for a MOS LSI of high speed and low power consumption.

In addition to the system LSI, the present invention can be widely applied to the case of manufacturing a semiconductor integrated circuits for various uses such as a microprocessor and a base band signal process LSI and lessening power consumption of signal process and fluctuations in a signal delay amount in an active mode.

In the specification, a P channel type MOS transistor is described with merely pMOS, and a N channel type MOS transistor is described with merely nMOS.

What is claimed is:

1. A semiconductor integrated circuit comprising:
a CMOS circuit for processing an input signal in an active mode;
a control switch for supplying a pMOS body bias voltage and an nMOS body bias voltage to an N well in a pMOS transistor and a P well in an nMOS transistor, respectively, in the CMOS circuit; and
a control memory for storing at least control information indicating whether or not the pMOS body bias voltage and the nMOS body bias voltage are supplied from the control switch to the N well in the pMOS transistor and the P well in the nMOS transistor, respectively, in the CMOS circuit in the active mode.

2. The semiconductor integrated circuit according to claim 1,
wherein the control memory is a nonvolatile memory, and
wherein information determining whether at least one of threshold voltages of the pMOS transistor and the nMOS transistor in the CMOS circuit is low or not can be stored in the nonvolatile memory as the control memory.

3. The semiconductor integrated circuit according to claim 2,
wherein a first operation voltage is supplied to a source of the pMOS transistor in the CMOS circuit and a second operation voltage is supplied to a source of the nMOS transistor, and
wherein the semiconductor integrated circuit further comprises:
a first voltage generator for generating the pMOS body bias voltage higher than the first operation voltage; and
a second voltage generator for generating the nMOS body bias voltage lower than the second operation voltage.

4. The semiconductor integrated circuit according to claim 2,
wherein a first operation voltage is supplied to a source of the pMOS transistor and a second operation voltage is supplied to a source of the nMOS transistor in the CMOS circuit,
wherein the control switch supplies an N-well standby voltage higher than the pMOS body bias voltage as a reverse body bias of the first operation voltage to the N well in the pMOS transistor in a standby mode, and
wherein the control switch applies a P-well standby voltage lower than the nMOS body bias voltage as a reverse body bias of the second operation voltage to the P well in the nMOS transistor in the standby mode.

5. The semiconductor integrated circuit according to claim 2,
wherein a first operation voltage is supplied to a source of the pMOS transistor and a second operation voltage is supplied to a source of the nMOS transistor in the CMOS circuit,
wherein the pMOS body bias voltage supplied to the N well is set as a reverse body bias of the first operation voltage supplied to the source of the pMOS transistor in the CMOS circuit, the nMOS body bias voltage supplied to the P well is set as a reverse body bias of the second operation voltage supplied to the source of the nMOS transistor in the CMOS circuit,
wherein, by supplying the pMOS body bias voltage set to a level higher than the first operation voltage to the N well, the pMOS transistor having the N well is controlled in a state of a high threshold voltage and a low leakage current, and
wherein, by supplying the nMOS body bias voltage set at a level lower than the second operation voltage to the P well, the nMOS transistor having the P well is controlled in a state of a high threshold voltage and a low leakage current.

6. The semiconductor integrated circuit according to claim 2,
wherein a first operation voltage is supplied to a source of the pMOS transistor and a second operation voltage is supplied to a source of the nMOS transistor in the CMOS circuit,
wherein the pMOS body bias voltage supplied to the N well is set as a forward body bias of the first operation voltage supplied to the source of the pMOS transistor in the CMOS circuit, the nMOS body bias voltage supplied to the P well is set as a forward body bias of the second operation voltage supplied to the source of the nMOS transistor in the CMOS circuit,
wherein, by supplying the pMOS body bias voltage set to a level lower than the first operation voltage to the N well, the pMOS transistor having the N well is controlled in a state of a low threshold voltage and a high leakage current, and
wherein, by supplying the nMOS body bias voltage set at a level higher than the second operation voltage to the P well, the nMOS transistor having the P well is controlled in a state of a low threshold voltage and a high leakage current.

7. The semiconductor integrated circuit according to claim 2,
wherein the control switch comprises:
a first control switch for supplying the pMOS body bias voltage to the N well in the pMOS transistor of the CMOS circuit; and
a second control switch for supplying the nMOS body bias voltage to the P well in the nMOS transistor in the CMOS circuit, and
wherein the control memory comprises:
a first control memory for storing at least first control information indicating whether or not the pMOS body bias voltage is supplied from the first control switch to the N well in the pMOS transistor in the CMOS circuit in the active mode; and
a second control memory for storing at least second control information indicating whether or not the nMOS body bias voltage is supplied from the second control switch to the P well in the nMOS transistor in the CMOS circuit in the active mode.

8. The semiconductor integrated circuit according to claim 2,
wherein a monitor pMOS transistor and a monitor nMOS transistor for evaluating a pMOS leakage current characteristic in the pMOS transistor and an nMOS leakage current characteristic in the nMOS transistor in the CMOS circuit are included in a chip.

9. The semiconductor integrated circuit according to claim 2,
wherein a first sense circuit for sensing a leakage current characteristic of the pMOS transistor in the CMOS circuit, a second sense circuit for sensing a leakage current characteristic of the nMOS transistor in the CMOS circuit, and a control unit are included in a chip, and
wherein in the case where measured leakage current in the pMOS and nMOS transistors changes from a past value by a predetermined allowable range or more, the control unit stores new control information into the control memory.

10. The semiconductor integrated circuit according to claim 2,
wherein the CMOS circuit for processing the input signal is a logic circuit,
wherein the semiconductor integrated circuit includes, in a chip, the CMOS circuit as the logic circuit and a CMOS-embedded SRAM,
wherein a memory cell in the CMOS-built-in SRAM includes a pair of driver nMOS transistors, a pair of load pMOS transistors, and a pair of transfer nMOS transistors, and
wherein the semiconductor integrated circuit further comprises:
a control switch for a embedded SRAM, for supplying a pMOS body bias voltage for the embedded SRAM and an nMOS body bias voltage for the embedded SRAM to N wells in a plurality of pMOS transistors and P wells in a plurality of nMOS transistors, respectively, in the CMOS-embedded SRAM; and
a control memory for the embedded SRAM for storing control information for the embedded SRAM, indicating whether or not the pMOS body bias voltage for the embedded SRAM and the nMOS body bias voltage for the embedded SRAM are supplied from the control switch for the embedded SRAM to the N wells in the pMOS transistors and the P wells in the nMOS transistors, respectively, in the CMOS-embedded SRAM.

11. The semiconductor integrated circuit according to claim 2,
wherein the pMOS transistor in the CMOS circuit is a pMOS transistor of an SOI structure, the nMOS transistor in the CMOS circuit is an nMOS transistor of the SOI structure, and
wherein a source and a drain of the pMOS transistor and a source and a drain of the nMOS transistor are formed in silicon over an insulating film in the SOI structure, and the N well in the pMOS transistor and the P well in the nMOS transistor are formed in a silicon substrate below the insulating film having the SOI structure.

12. A semiconductor integrated circuit comprising:
a MOS circuit for processing an input signal in an active mode;
a control switch for supplying a MOS body bias voltage to a well in a MOS transistor in the MOS circuit; and
a control memory for storing control information indicating whether or not the MOS body bias voltage is supplied from the control switch to the well in the MOS transistor in the MOS circuit at least in the active mode.

13. The semiconductor integrated circuit according to claim 12,
wherein the control memory is a nonvolatile memory, and
wherein information determining whether threshold voltage of the MOS transistor in the MOS circuit is low or not can be stored in the nonvolatile memory as the control memory.

14. The semiconductor integrated circuit according to claim 13,
wherein an operation voltage is supplied to a source of the MOS transistor in the MOS circuit, and
wherein the semiconductor integrated circuit comprises a voltage generator for generating the MOS body bias voltage higher than the operation voltage.

15. The semiconductor integrated circuit according to claim 14,
wherein the control switch supplies a well standby voltage higher than the MOS body bias voltage as a reverse body bias of the operation voltage to the well in the MOS transistor in a standby mode.

16. The semiconductor integrated circuit according to claim 13,
wherein an operation voltage is supplied to a source of the MOS transistor in the MOS circuit,
wherein the MOS body bias voltage supplied to the well is set as a reverse body bias of the operation voltage supplied to the source of the MOS transistor in the MOS circuit, and
wherein, by supplying the MOS body bias voltage set to a level higher than the operation voltage to the well, the MOS transistor having the well is controlled in a state of a high threshold voltage and a low leakage current.

17. The semiconductor integrated circuit according to claim 13,
wherein an operation voltage is supplied to a source of the MOS transistor in the MOS circuit,
wherein the MOS body bias voltage supplied to the well is set as a forward body bias of the operation voltage supplied to the source of the MOS transistor in the MOS circuit, and
wherein, by supplying the MOS body bias voltage set to a level lower than the operation voltage to the well, the MOS transistor having the well is controlled in a state of a low threshold voltage and a high leakage current.

18. The semiconductor integrated circuit according to claim 13,
wherein a monitor MOS transistor for evaluating a leakage current characteristic of the MOS transistor in the MOS circuit is included in a chip.

19. The semiconductor integrated circuit according to claim 13,
wherein a sense circuit for sensing a leakage current characteristic of the MOS transistor in the MOS circuit and a control unit are included in a chip, and
wherein in the case where measured leakage current in the MOS transistor changes from a past value by a predetermined allowable range or more, the control unit stores new control information into the control memory.

20. The semiconductor integrated circuit according to claim 13,
wherein the MOS transistor in the MOS circuit is a MOS transistor of an SOI structure,
wherein a source and a drain of the MOS transistor are formed in silicon over an insulating film in the SOI structure, and
wherein the well in the MOS transistor is formed in a silicon substrate below the insulating film having the SOI structure.

21. A method of manufacturing a semiconductor integrated circuit, including a step of preparing a wafer which includes a chip of a semiconductor integrated circuit comprising a CMOS circuit, a control switch, and a control memory,
the CMOS circuit processing an input signal in an active mode,
the control switch supplying a pMOS body bias voltage and an nMOS body bias voltage to an N well in a pMOS transistor and a P well in an nMOS transistor, respectively, in the CMOS circuit, and
the control memory being a nonvolatile memory for storing, in a nonvolatile manner, control information indicating whether or not the pMOS body bias voltage and the nMOS body bias voltage are supplied from the control switch to the N well in the pMOS transistor and the P well in the nMOS transistor, respectively, in the CMOS circuit at least in the active mode,
the method comprising the steps of:
measuring at least one of threshold voltages of the pMOS transistor and the nMOS transistor in the CMOS circuit;
determining whether the measured threshold voltage is lower than a target or not; and
storing, in a nonvolatile manner, a result of the determination as the control information into the control memory.

22. The method of manufacturing a semiconductor integrated circuit according to claim 21,
wherein the CMOS circuit for processing the input signal is a logic circuit,
wherein the semiconductor integrated circuit includes, in a chip, the CMOS circuit as the logic circuit and a CMOS-embedded SRAM,
wherein a memory cell in the CMOS-embedded SRAM includes a pair of driver nMOS transistors, a pair of load pMOS transistors, and a pair of transfer nMOS transistors,
wherein the semiconductor integrated circuit further comprises:
a control switch for a embedded SRAM, for supplying a pMOS body bias voltage for the embedded SRAM and an nMOS body bias voltage for the embedded SRAM to N wells in a plurality of pMOS transistors and P wells in a plurality of nMOS transistors, respectively, in the CMOS-embedded SRAM; and
a control memory for the embedded SRAM for storing, in a nonvolatile manner, control information for the embedded SRAM, indicating whether or not the pMOS body bias voltage for the embedded SRAM and the nMOS body bias voltage for the embedded SRAM are supplied from the control switch for the embedded SRAM to the N wells in the pMOS transistors and the P wells in the nMOS transistors, respectively, in the CMOS-embedded SRAM, and
wherein threshold voltages of the pMOS transistor and the nMOS transistor in the CMOS-embedded SRAM are measured, whether the measured threshold voltage is lower than a target or not is determined, and a result of the determination is stored as the control information for the embedded-SRAM into the control memory for the embedded-SRAM in a nonvolatile manner.
